(19) United States
(12) Patent Application Publication
(10) Pub. No.: US 2025/0176357 A1
(43) Pub. Date: May 29, 2025

(54) DISPLAY DEVICE

(71) Applicant: Samsung Display Co., LTD., Yongin-si (KR)

(72) Inventors: Jong Woo JIN, Yongin-si (KR); Ki Hwan KIM, Yongin-si (KR)

(73) Assignee: Samsung Display Co., LTD., Yongin-si (KR)

(21) Appl. No.: 18/738,350

(22) Filed: Jun. 10, 2024

(30) Foreign Application Priority Data
Nov. 28, 2023 (KR) 10-2023-0167532

(51) Int. Cl. H10K 59/121

(52) U.S. Cl. CPC H10K 59/1213

(57) ABSTRACT

A display device includes: an active layer disposed on a substrate; a gate electrode disposed on the active layer to overlap the active layer and define a channel region of the active layer; a pixel electrode disposed on the gate electrode; a light emitting layer disposed on the pixel electrode; and a common electrode disposed on the light emitting layer. In the channel region having a channel length in a first direction, at least one side of the channel region that defines the channel length has a diagonal shape or a curved shape such that the channel length varies along a second direction intersecting the first direction.

### CROSS REFERENCE TO RELATED APPLICATION(S)

This application claims priority to and the benefit of Korean Patent Application No. 10-2023-0167532 under 35 U.S.C. § 119, filed on Nov. 28, 2023, in the Korean Intellectual Property Office, the disclosure of which is incorporated herein in its entirety by reference.

### BACKGROUND

### 1. Technical Field

The present disclosure relates to a display device, and more particularly, to a display device that includes a plurality of emission areas, e.g., pixel circuits, and which can express fine gradations of an image displayed by the display device by expanding a driving range of a voltage applied via driving lines to the emission areas.

### 2. Description of the Related Art

Organic light emitting diode (OLED) displays have self-luminous properties and, unlike liquid crystal displays (LCDs), do not require a separate light source, thus reducing thickness and weight. In addition, organic light emitting diode displays are drawing attention as next-generation displays for TVs, monitors, and portable electronic devices due to their high-quality characteristics such as low power consumption, high luminance, and high response speed.

### SUMMARY

Aspects of the present disclosure provide a display device that can express fine gradations by expanding a driving range of OLEDs included in the display device.

According to an aspect of the present disclosure, there is provided a display device having a channel region with a channel length that has a diagonal shape or a curved shape so that the channel length varies one direction.

According to an embodiment of the disclosure, a display device includes an active layer disposed on a substrate; a gate electrode disposed on the active layer to overlap the active layer and define a channel region of the active layer; a pixel electrode disposed on the gate electrode; a light emitting layer disposed on the pixel electrode; and a common electrode disposed on the light emitting layer, wherein in the channel region having a channel length in a first direction, at least one side of the channel region that defines the channel length has a diagonal shape or a curved shape such that the channel length varies along a second direction intersecting the first direction.

In an embodiment, the channel region may have a trapezoidal shape.

In an embodiment, the gate electrode may have a trapezoidal shape.

In an embodiment, the active layer may have a rectangular shape.

In an embodiment, the gate electrode may have a quadrangular shape.

In an embodiment, the active layer may have a quadrangular shape with both sides bent inwardly or outwardly with respect to each other.

In an embodiment, the channel region may have an arc shape.

In an embodiment, the gate electrode may have a trapezoidal shape.

In an embodiment, the active layer may have an arc shape.

In an embodiment, the gate electrode may have a quadrangular shape.

In an embodiment, the active layer may have an arc shape.

In an embodiment, the channel region may have a hexagonal shape.

In an embodiment, the gate electrode may have a hexagonal shape.

In an embodiment, the channel region may include a first region having a quadrangular shape; a second region having a quadrangular shape; and a third region disposed between the first region and the second region and having a hexagonal shape.

In an embodiment, the channel region may include a first region having a quadrangular shape; a second region having a quadrangular shape; and a third region disposed between the first region and the second region and having an octagonal shape.

In an embodiment, the channel region may include a first region having a quadrangular shape; a second region having a quadrangular shape; and a third region disposed between the first region and the second region and having an elliptical shape.

In an embodiment, the entire third region may overlap the active layer.

In an embodiment, a portion of the third region may overlap the active layer.

In an embodiment, the channel region may include a first region having a quadrangular shape; a second region having a quadrangular shape; a third region disposed between the first region and the second region and having a trapezoidal shape; and a fourth region disposed between the second region and the third region and having an inverted trapezoidal shape.

In an embodiment, the channel region may include a first region having a quadrangular shape; a second region having a quadrangular shape; a third region disposed between the first region and the second region and having a trapezoidal shape; a fourth region disposed between the third region and the second region and having an inverted trapezoidal shape; and a fifth region disposed between the fourth region and the third region and having a quadrangular shape.

In an embodiment, the channel region may have semicircular grooves respectively formed on both sides facing each other in the first direction.

In an embodiment, the channel region may have semi-elliptical grooves respectively formed on both sides facing each other in the first direction.

In an embodiment, the channel region may include a first region having a trapezoidal shape; and a second region spaced apart from the first region in the first direction and having an inverted trapezoidal shape.

According to an embodiment of the disclosure, an organic light emitting diode includes an active layer disposed on a substrate; a gate electrode disposed on the active layer to overlap the active layer and define a channel region of the active layer; wherein in the channel region having a channel length, at least one side of the channel region that defines the channel length has a diagonal shape or a curved shape such that the channel length varies in a direction different from a direction in which the channel length extends.

According to the display device according to the present disclosure, a display device may express fine gradations by expanding a driving range.

The effects of the present disclosure are not limited to the above-described effects and other effects that are not described herein will become apparent to those skilled in the art from the following description.

### BRIEF DESCRIPTION OF THE DRAWINGS

In the drawings, the sizes, thicknesses, ratios, and dimensions of the elements may be exaggerated for ease of description and for clarity. Like reference numbers and/or like reference characters refer to like elements throughout. These and/or other aspects will become apparent and more readily appreciated from the following description of the embodiments, taken in conjunction with the accompanying drawings in which:

FIG. 1 is a perspective view of a display device according to an embodiment that is constructed according to principles of the disclosure;

FIG. 2 is a cross-sectional view of the display device according to the embodiment;

FIG. 3 is a plan view of a display unit of the display device according to the embodiment;

FIG. 4 is a block diagram of a display panel and a display driver according to an embodiment;

FIG. 5 is a circuit diagram of a pixel of the display device according to the embodiment;

FIG. 6 is a cross-sectional view of the display device including a first transistor of FIG. 5;

FIG. 7 is a plan view of a transistor according to an embodiment;

FIG. 8 is a plan view of a transistor according to an embodiment;

FIG. 9 is a plan view of a transistor according to an embodiment;

FIG. 10 is a plan view of a transistor according to an embodiment;

FIG. 11 is a plan view of a transistor according to an embodiment;

FIG. 12 is a plan view of a transistor according to an embodiment;

FIG. 13 is a plan view of a transistor according to an embodiment;

FIG. 14 is a plan view of a transistor according to an embodiment;

FIG. 15 is a plan view of a transistor according to an embodiment;

FIG. 16 is a plan view of a transistor according to an embodiment;

FIG. 17 is a plan view of a transistor according to an embodiment;

FIG. 18 is a plan view of a transistor according to an embodiment;

FIG. 19 is a plan view of a transistor according to an embodiment;

FIG. 20 is a plan view of a transistor according to an embodiment; and

FIG. 21 is a diagram for explaining the operation of a transistor of a display device according to an embodiment.

### DETAILED DESCRIPTION OF THE EMBODIMENTS

Advantages and features of the present disclosure and methods to achieve them will become apparent from the descriptions of embodiments hereinbelow with reference to the accompanying drawings. However, the present disclosure is not limited to embodiments disclosed herein but may be implemented in various different ways. The embodiments are provided for making the disclosure of the present disclosure thorough and for fully conveying the scope of the present disclosure to those skilled in the art. It is to be noted that the scope of the present disclosure is defined only by the claims.

As used herein, a phrase “an element A on an element B” refers to that the element A may be disposed directly on the element B and/or the element A may be disposed indirectly on the element B via another element C. Like reference numerals denote like elements throughout the descriptions. The figures, dimensions, ratios, angles, numbers of elements given in the drawings are merely illustrative and are not limiting.

Although terms such as first, second, etc. are used to distinguish arbitrarily between the elements such terms describe, and thus these terms are not necessarily intended to indicate temporal or other prioritization of such elements. These terms are used to merely distinguish one element from another. Accordingly, as used herein, a first element may be a second element within the technical scope of the present disclosure.

Features of various embodiments of the present disclosure may be combined partially or totally. As will be clearly appreciated by those skilled in the art, technically various interactions and operations are possible. Various embodiments can be practiced individually or in combination.

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing illustrative features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the x, y, and z axes, and may be interpreted in a broader sense. For example, the DR1-axis, the DR2-axis, and the DR3-axis may be perpendicular to one another, or may represent different directions that are not perpendicular to one another. For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the illustrative term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some illustrative embodiments may be physically separated into two or more interacting and discrete blocks, units, and/or modules without departing from the scope of the inventive concepts. Further, the blocks, units, and/or modules of some illustrative embodiments may be physically combined into more complex blocks, units, and/or modules without departing from the scope of the inventive concepts.

Hereinafter, embodiments of the present disclosure will be described with reference to the accompanying drawings.

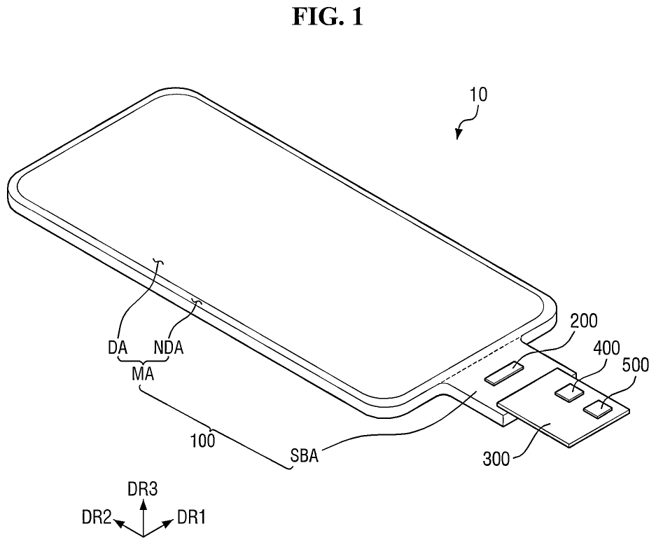

FIG. 1 is a perspective view of a display device 10 according to an embodiment that is constructed according to principles of the disclosure.

Referring to FIG. 1, the display device 10 may be applied to portable electronic devices such as mobile phones, smartphones, tablet personal computers (PCs), mobile communication terminals, electronic notebooks, electronic books, portable multimedia players (PMPs), navigation devices, and ultra-mobile PCs (UMPCs). For example, the display device 10 may be applied as a display unit of a television, a notebook computer, a monitor, a billboard, or an Internet of things (IoT) device. For another example, the display device 10 may be applied to wearable devices such as smart watches, watch phones, glasses-type displays, and head mounted displays (HMDs).

The display device 10 may have a planar shape similar to a quadrangle, or otherwise referred to herein as a three-dimensional rectangular shape. For example, the display device 10 may have a planar shape similar to a quadrangle having short sides in a first direction DR1 and long sides in a second direction DR2. Each corner where a short side extending in the first direction DR1 meets a long side extending in the second direction DR2 may be rounded with a predetermined curvature or may be right-angled. The planar shape of the display device 10 is not limited to the quadrangular shape but may also be similar to other polygonal shapes, a circular shape, or an elliptical shape.

The display device 10 may include a display panel 100, a display driver 200, a circuit board 300, a touch driver 400, and a power supply unit 500.

The display panel 100 may include a main area MA and a sub-area SBA.

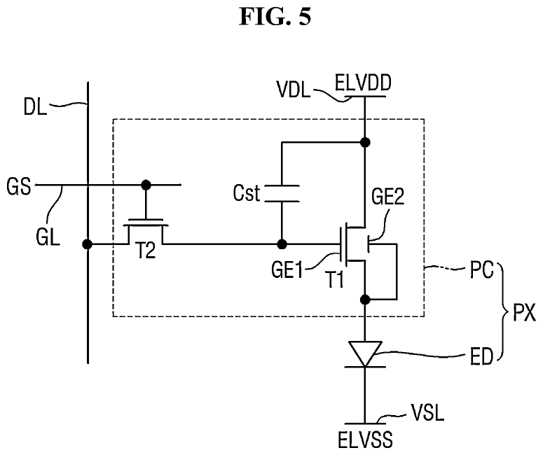

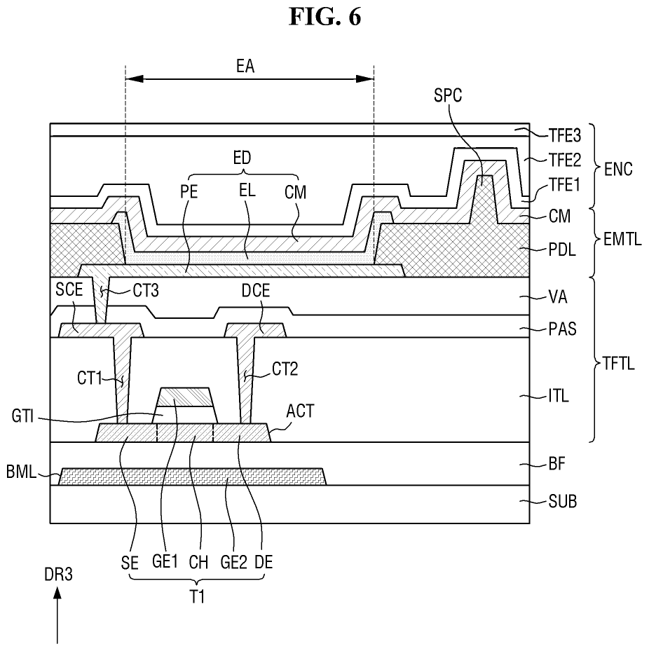

The main area MA may include a display area DA including pixels that display an image and a non-display area NDA disposed around the display area DA (that is, on a periphery, or outer portion with respect to a plan view, of the display area DA). The display area DA may emit light from a plurality of emission areas or a plurality of opening areas. For example, the display panel 100 may include pixel circuits including switching elements, a pixel defining layer defining the emission areas or the opening areas, and self-light emitting elements ED (sce, e.g., FIG. 5 and FIG. 6).

For example, each of the self-light emitting elements ED may include, but is not limited to, at least one of an organic light emitting diode including an organic light emitting layer, a quantum dot light emitting diode including a quantum dot light emitting layer, an inorganic light emitting diode including an inorganic semiconductor, and a micro light emitting diode.

The non-display area NDA may be an area outside the display area DA, such as is shown in FIG. 1. The non-display area NDA may be defined as an edge area of the main area MA of the display panel 100. The non-display area NDA may include a gate driver (that supplies gate signals to gate lines and fan-out lines that connect the display driver 200 and the display area DA.

The sub-area SBA may extend from a side of the main area MA, such as from a bottom side of the main area MA as shown in FIG. 1. The sub-area SBA may include a flexible material that can be bent, folded, rolled, etc. For example, in case that the sub-area SBA is bent, it may be overlapped by the main area MA in a thickness direction (e.g., a third direction DR3). The sub-area SBA may include the display driver 200 and pad units connected to the circuit board 300. Optionally, the sub-area SBA may be omitted in some implementations, and the display driver 200 and the pad units may be disposed in the non-display area NDA.

The display driver 200 may output signals and voltages for driving the display panel 100. The display driver 200 may supply data voltages to data lines. The display driver 200 may supply a power supply voltage to a power line and supply a gate control signal to the gate driver. The display driver 200 may be formed as an integrated circuit and mounted on the display panel 100 by a chip on glass (COG) method, a chip on plastic (COP) method, or an ultrasonic bonding method. For example, the display driver 200 may be disposed in the sub-area SBA and may be overlapped by the main area MA in the thickness direction (third direction DR3) by the bending of the sub-area SBA. As another example, the display driver 200 may be mounted on the circuit board 300.

The circuit board 300 may be attached onto the pad units of the display panel 100 using an anisotropic conductive film. Lead lines of the circuit board 300 may be electrically connected to the pad units of the display panel 100. The circuit board 300 may be a flexible printed circuit board, a printed circuit board, or a flexible film such as a chip on film.

The touch driver 400 may be mounted on the circuit board 300. The touch driver 400 may be electrically connected to a touch sensing unit of the display panel 100. The touch driver 400 may supply a touch driving signal to a plurality of touch electrodes of the touch sensing unit and sense a change in capacitance between the touch electrodes. For example, the touch driving signal may be a pulse signal having a predetermined frequency. The touch driver 400 may determine whether an input has been made and calculate coordinates of the input based on a change in capacitance between the touch electrodes. The touch driver 400 may be formed as an integrated circuit (IC).

The power supply unit 500 may be disposed on the circuit board 300 to supply a power supply voltage to the display driver 200 and the display panel 100. The power supply unit 500 may generate a first driving voltage and supply the first driving voltage to first driving voltage lines VDL, may generate initialization voltages (e.g., a first initialization voltage and a second initialization voltage) and supply the initialization voltages to initialization voltage lines (e.g. a first initialization voltage line VIL1 and a second initialization voltage line VIL2), and may generate a common voltage and supply the common voltage to a common electrode common to light emitting elements ED of a plurality of pixels. For example, the first driving voltage may be a high potential voltage for driving the light emitting elements ED, and the common voltage may be a low potential voltage for driving the light emitting elements ED.

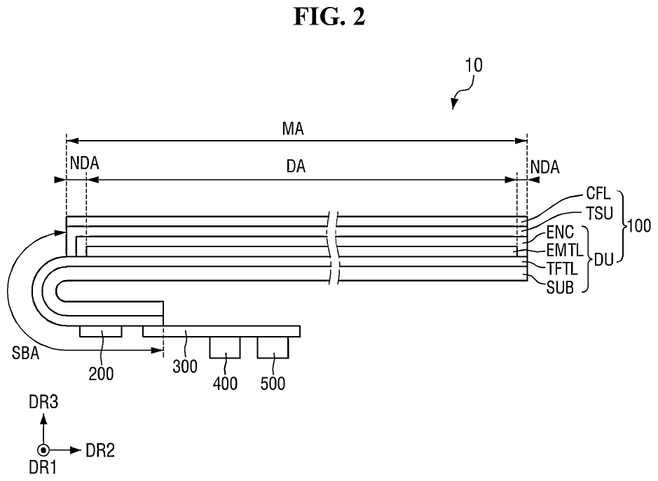

FIG. 2 is a cross-sectional view of the display device 10 according to the embodiment.

Referring to FIG. 2, the display panel 100 may include a display unit DU, a touch sensing unit TSU, and a color filter layer CFL. The display unit DU may include a substrate SUB, a thin-film transistor layer TFTL, a light emitting element layer EMTL, and an encapsulation layer ENC.

The substrate SUB may be a base substrate or a base member. The substrate SUB may be a flexible substrate that can be bent, folded, rolled, etc. For example, the substrate SUB may include polymer resin such as polyimide (PI), but the present disclosure is not limited thereto. For another example, the substrate SUB may include a glass material or a metal material.

The thin film transistor layer TFTL may be disposed on the substrate SUB. The thin-film transistor layer TFTL may include a plurality of thin-film transistors constituting pixel circuits of pixels. The thin-film transistor layer TFTL may further include gate lines, data lines, power lines, gate control lines, fan-out lines connecting the display driver 200 and the data lines, and lead lines connecting the display driver 200 and pad units. Each of the thin-film transistors may include a semiconductor region, a source electrode, a drain electrode, and a gate electrode. For example, in case that the gate driver is formed on a side of the non-display area NDA of the display panel 100, the gate driver may include thin-film transistors.

The thin-film transistor layer TFTL may be disposed in the display area DA, the non-display area NDA, and the sub-area SBA. The thin-film transistors of the pixels, the gate lines, the data lines, and the power lines of the thin-film transistor layer TFTL may be disposed in the display area DA. The gate control lines and the fan-out lines of the thin-film transistor layer TFTL may be disposed in the non-display area NDA. The lead lines of the thin-film transistor layer TFTL may be disposed in the sub-area SBA.

The light emitting element layer EMTL may be disposed on the thin-film transistor layer TFTL. The light emitting element layer EMTL may include a plurality of light emitting elements ED, each including a pixel electrode, a light emitting layer and a common electrode sequentially stacked to emit light, and a pixel defining layer defining the pixels. The light emitting elements ED of the light emitting element layer EMTL may be disposed in the display area DA.

For example, the light emitting layer may be an organic light emitting layer including an organic material. The light emitting layer may include a hole transporting layer, an organic light emitting layer, and an electron transporting layer. In case that the pixel electrode receives a voltage (e.g., a predetermined or selectable voltage) through a thin-film transistor of the thin film transistor layer TFTL and the common electrode receives a cathode voltage, holes and electrons may move to the organic light emitting layer through the hole transporting layer and the electron transporting layer, respectively. Then, the holes and the electrons may be combined with each other in the organic light emitting layer to emit light. For example, the pixel electrode may be an anode, and the common electrode may be a cathode, but the present disclosure is not limited thereto.

For another example, each of the light emitting elements ED may include a quantum dot light emitting diode including a quantum dot light emitting layer, an inorganic light emitting diode including an inorganic semiconductor, or a micro light emitting diode.

The encapsulation layer ENC may cover upper and side surfaces of the light emitting element layer EMTL and may protect the light emitting element layer EMTL. The encapsulation layer ENC may include at least one inorganic layer and at least one organic layer to encapsulate the light emitting element layer EMTL.

The touch sensing unit TSU may be disposed on the encapsulation layer ENC. The touch sensing unit TSU may include a plurality of touch electrodes for sensing a user's touch in a capacitive manner and touch lines connecting the touch electrodes and the touch driver 400. For example, the touch sensing unit TSU may sense a user's touch in a mutual capacitance manner or a self-capacitance manner, as is known to a person of ordinary skill in the art.

For another example, the touch sensing unit TSU may be disposed on a separate substrate SUB disposed on the display unit DU. In this case, the substrate SUB that supports the touch sensing unit TSU may be a base member that encapsulates the display unit DU.

The touch electrodes of the touch sensing unit TSU may be disposed in a touch sensor area overlapping the display area DA. The touch lines of the touch sensing unit TSU may be disposed in a touch peripheral area overlapping the non-display area NDA.

The color filter layer CFL may be disposed on the touch sensing unit TSU. The color filter layer CFL may include a plurality of color filters corresponding to a plurality of emission areas, respectively. Each of the color filters may selectively transmit light of a specific wavelength and block or absorb light of other wavelengths. The color filter layer CFL may absorb a part of light coming from the outside of the display device 10, thereby reducing reflected light caused by the external light. Therefore, the color filter layer CFL can prevent color distortion caused by reflection of external light.

Since the color filter layer CFL is directly disposed on the touch sensing unit TSU, the display device 10 may not require a separate substrate for the color filter layer CFL. Therefore, a thickness of the display device 10 may be relatively reduced.

The sub-area SBA of the display panel 100 may extend from a side of the main area MA. The sub-area SBA may include a flexible material that can be bent, folded, rolled, etc. For example, in case that the sub-area SBA is bent, it may be overlapped by the main area MA in the thickness direction (third direction DR3). The sub-area SBA may include the display driver 200 and the pad units electrically connected to the circuit board 300.

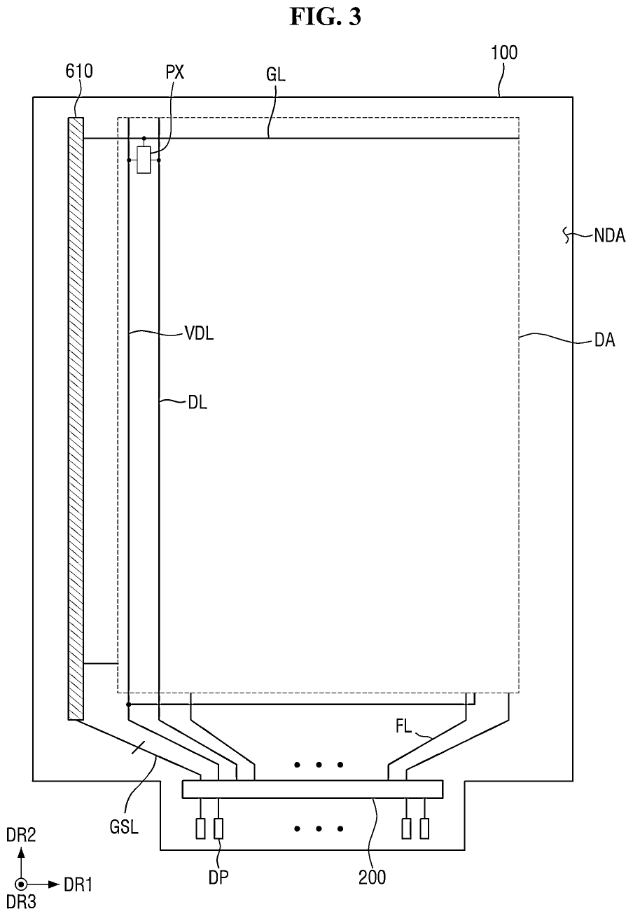

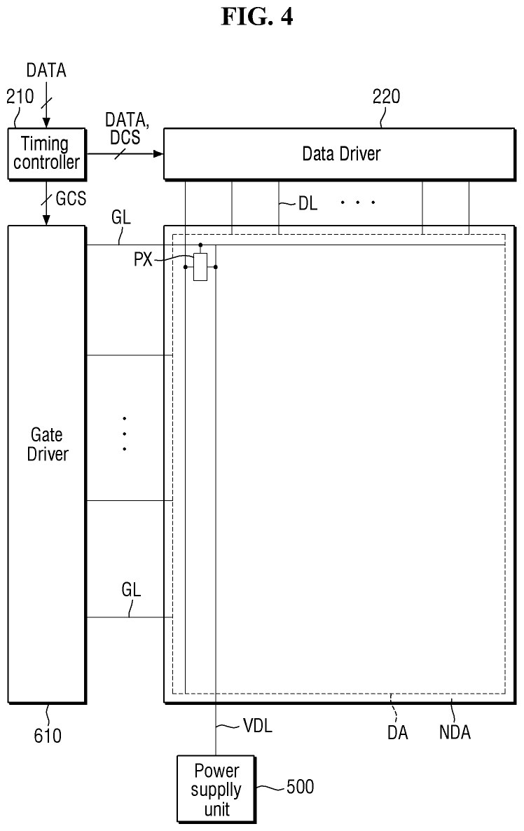

FIG. 3 is a plan view of the display unit DU of the display device 10 according to an embodiment. FIG. 4 is a block diagram of the display panel 100 and the display driver 200 according to an embodiment.

Referring to FIGS. 3 and 4, the display panel 100 may include the display area DA and the non-display area NDA.

The display area DA may include a plurality of pixels PX, a plurality of driving voltage lines VDL connected to the pixels PX, a plurality of common voltage lines (e.g., VSL in FIG. 5), a plurality of gate lines GL, and a plurality of data lines DL.

Each of the pixels PX may be connected to a gate line GL, a data line DL, a driving voltage line VDL, and a common voltage line VSL. Each of the pixels PX may include at least one transistor, a light emitting element ED, and a capacitor.

The gate lines GL may extend in the first direction DR1 and may be spaced apart from each other in the second direction DR2 intersecting the first direction DR1. The gate lines GL may be arranged along the second direction DR2. The gate lines GL may sequentially supply gate signals to the pixels PX.

The data lines DL may extend in the second direction DR2 and may be spaced apart from each other in the first direction DR1. The data lines DL may be arranged along the first direction DR1. The data lines DL may supply data voltages to the pixels PX. A data voltage may determine the luminance of each of the pixels PX. According to an embodiment, one pixel may be connected to two different data lines. For example, one pixel may be connected to a first data line DL1 and a second data line DL2.

The driving voltage lines VDL may extend in the second direction DR2 and may be spaced apart from each other in the first direction DR1. The driving voltage lines VDL may be arranged along the first direction DR1. The driving voltage lines VDL may supply driving voltages to the pixels PX. The driving voltages may be high potential voltages for driving the light emitting elements ED of the pixels PX.

The non-display area NDA may surround the display area DA. The non-display area NDA may include a gate driver 610, fan-out lines FL, and a gate control line GSL.

The fan-out lines FL may extend from the display driver 200 to the display area DA. The fan-out lines FL may supply data voltages received from the display driver 200 to the data lines DL.

The gate control line GSL may extend from the display driver 200 to the gate driver 610. The gate control line GSL may supply a gate control signal GCS received from the display driver 200 to the gate driver 610.

The sub-area SBA may extend from a side of the non-display area NDA. The sub-area SBA may include the display driver 200 and pad units DP. The pad units DP may be disposed closer to an edge of the sub-area SBA than the display driver 200. The pad units DP may be electrically connected to the circuit board 300 through an anisotropic conductive film.

With reference to FIG. 4, the display driver 200 may include a timing controller 210 and a data driver 220.

The timing controller 210 may receive digital video data DATA and timing signals from the circuit board 300. The timing controller 210 may control the operation timing of the data driver 220 by generating a data control signal DCS based on the timing signals, may control the operation timing of the gate driver 610 by generating the gate control signal GCS, and may control the operation timing of an emission control driver 620 by generating an emission control signal ECS. The timing controller 210 may supply the gate control signal GCS to the gate driver 610 through the gate control line GSL. The timing controller 210 may supply the digital video data DATA and the data control signal DCS to the data driver 220.

The data driver 220 may convert the digital video data DATA into analog data voltages and supply the analog data voltages to the data lines DL through the fan-out lines FL. Gate signals of the gate driver 610 may select pixels PX to which the data voltages are to be supplied, and the selected pixels PX may receive the data voltages through the data lines DL.

The power supply unit 500 may be disposed on the circuit board 300 to supply a power supply voltage to the display driver 200 and the display panel 100. The power supply unit 500 may generate a first driving voltage and supply the first driving voltage to the driving voltage lines VDL, may generate initialization voltages and supply the initialization voltages to initialization voltage lines, and may generate a common voltage and supply the common voltage to a common electrode common to the light emitting elements ED of the pixels PX. The common voltage may be applied to the common electrode through a common voltage line VSL.

The gate driver 610 may be disposed outside one side of the display area DA or on one side of the non-display area NDA, and the emission control driver may be disposed outside the other side of the display area DA or on the other side of the non-display area NDA. However, the present disclosure is not limited thereto. For another example, the gate driver 610 and the emission control driver 620 may be disposed on either one side or the other side of the non-display area NDA.

The gate driver 610 may include a plurality of transistors that generate gate signals based on the gate control signal GCS. The transistors of the gate driver 610 may be formed on the same layer as the transistors of the pixels PX. The gate driver 610 may supply gate signals to the gate lines GL.

FIG. 5 is a circuit diagram of a pixel PX of the display device 10 according to the embodiment.

Referring to FIG. 5, the pixel PX may be connected to a gate line GL, a data line DL, a driving voltage line VDL, and a common voltage line VSL.

The pixel PX may include a pixel circuit PC and a light emitting element ED.

The pixel circuit PC may include a first transistor T1, a second transistor T2, and a capacitor Cst.

The first transistor T1 may include a first gate electrode GE1, a second gate electrode GE2, a source electrode, and a drain electrode. The first transistor T1 may control a source-drain current (hereinafter referred to as a driving current) according to a data voltage applied to the first gate electrode GE1. The first transistor T1 may have the first gate electrode GE1 electrically connected to a source electrode of the second transistor T2, the second gate electrode GE2 electrically connected to a source electrode of a first transistor T1, the drain electrode electrically connected to the driving voltage line VDL, and the source electrode connected to a first electrode (or an anode or a pixel electrode) of the light emitting element ED. The driving voltage line VDL may transmit a driving voltage ELVDD.

The light emitting element ED may emit light in response to a driving current Isd received. The amount of light or luminance of the light emitting element ED may be proportional to the magnitude of the driving current Isd. The light emitting element ED may include the first electrode, a second electrode (or a cathode or a common electrode) and an organic light emitting layer, and the organic light emitting layer may be disposed between the first electrode and the second electrode. For another example, the light emitting element ED may be an inorganic light emitting element ED that may include a first electrode, a second electrode and an inorganic semiconductor, and the inorganic semiconductor may be disposed between the first electrode and the second electrode. For another example, the light emitting element ED may be a quantum dot light emitting element ED that may include a first electrode, a second electrode and a quantum dot light emitting layer, and the quantum dot light emitting layer may be disposed between the first electrode and the second electrode. For another example, the light emitting element ED may be a micro light emitting diode. The first electrode of the light emitting element ED may be electrically connected to the source electrode of the first transistor T1. The second electrode of the light emitting element ED may be connected to the common voltage line VSL. The second electrode of the light emitting element ED may receive a common voltage ELVSS (e.g., a low potential voltage) from the common voltage line VSL.

The second transistor T2 may be turned on by a gate signal GS of the gate line GL to electrically connect the data line DL and the first gate electrode GE1 of the first transistor T1. The second transistor T2 turned on based on the gate signal GS may supply a data voltage from the data line DL to the first gate electrode GE1 of the first transistor T1. The second transistor T2 may have a gate electrode electrically connected to the gate line GL, a drain electrode electrically connected to the data line DL, and the source electrode electrically connected to the first gate electrode of the first transistor T1.

The capacitor Cst may be electrically connected between a gate electrode of the first transistor T1 and the driving voltage line VDL. A first electrode of the capacitor Cst may be electrically connected to the first gate electrode GE1 of the first transistor T1, and a second electrode of the capacitor Cst may be electrically connected to the driving voltage line VDL. For example, the capacitor Cst may store the data voltage supplied from the data line DL through the second transistor T2.

Each of the first transistor T1 and the second transistor T2 may include an oxide-based active layer. The oxide-based active layer may include, for example, indium-gallium-zinc-oxide (IGZO) or indium-gallium-zinc-tin oxide (IGZTO). A transistor including the oxide-based active layer may have a coplanar structure in which a gate electrode is disposed at the top of the coplanar structure. The transistor including the oxide-based active layer may correspond to an n-type transistor and may output an electric current flowing into a drain electrode to a source electrode based on a gate-high voltage applied to a gate electrode.

FIG. 6 is a cross-sectional view of the display device 10 including the first transistor T1 of FIG. 5.

Referring to FIG. 6, the display device 10 according to the embodiment may include the substrate SUB, a light blocking layer BML, a buffer layer BF, the transistor layer TFTL, the light emitting element layer EMTL, and the encapsulation layer ENC. The light blocking layer BML, the buffer layer BF, the transistor layer TFTL, the light emitting element layer EMTL, and the encapsulation layer ENC may be sequentially disposed in a downwards to upwards direction on the substrate SUB along the third direction DR3. Here, the transistor layer TFTL may include the first transistor T1 and the second transistor T2 of FIG. 5 described above. In FIG. 6, the first transistor T1 included in the transistor layer TFTL is illustrated as an example.

The substrate SUB may be a rigid substrate or a flexible substrate that can be bent, folded, or rolled. The substrate SUB may be made of an insulating material such as glass, quartz, or polymer resin. The polymer material may be, for example, polyethersulphone (PES), polyacrylate (PA), polyarylate (PAR), polyetherimide (PEI), polyethylene naphthalate (PEN), polyethylene terepthalate (PET), polyphenylene sulfide (PPS), polyallylate, polyimide (PI), polycarbonate (PC), cellulose triacetate (CAT), cellulose acetate propionate (CAP), or a combination thereof. Alternatively, the substrate SUB may include a metal material.

The light blocking layer BML may be disposed on the substrate SUB. The light blocking layer BML may be disposed on the substrate SUB and overlapped by an active layer ACT that will be described later in more detail. The light blocking layer BML may be made of, for example, a metal material such as chromium (Cr) or molybdenum (Mo) or may be made of black ink or black dye. In case that the light blocking layer BML is made of a metal material, it may receive static power. Accordingly, the light blocking layer BML may not float electrically, and the electrical characteristics of the transistors T1 and T2 on the light blocking layer BML may be stabilized. For example, performance degradation of the oxide-based transistors T1 and T2 can be minimized. Oxide semiconductors are sensitive to light, and changes in current amount may occur due to external light. The light blocking layer BML may include the second gate electrode GE2 of the first transistor T1. In other words, a portion of the light blocking layer BML may correspond to the second gate electrode GE2 of the first transistor T1.

The buffer layer BF may be disposed on the light blocking layer BML. The buffer layer BF may be disposed on the entire surface of the substrate SUB including the light blocking layer BML. The buffer layer BF may be a layer for protecting transistors of the thin-film transistor layer TFTL and a light emitting layer EL of the light emitting element layer EMTL from moisture introduced through the substrate SUB which is vulnerable to moisture penetration. The buffer layer BF may be composed of a plurality of inorganic layers stacked alternately. For example, the buffer layer BF may be a multilayer in which one or more inorganic layers selected from a silicon nitride layer, a silicon oxynitride layer, a silicon oxide layer, a titanium oxide layer, and an aluminum oxide layer are alternately stacked.

The active layer ACT may be disposed on the buffer layer BF. For example, the active layer ACT may be disposed on the buffer layer BF to overlap the first gate electrode GE1 of the light blocking layer BML. The active layer ACT may be, for example, an oxide semiconductor. For example, the active layer ACT may be a semiconductor including indium-gallium-zinc-oxide (IGZO) or indium-gallium-zinc-tin oxide (IGZTO). In addition, the active layer ACT may be, for example, crystalline silicon, polycrystalline silicon, or amorphous silicon.

A gate insulating layer GTI may be disposed on the active layer ACT. For example, the gate insulating layer GTI may overlap a channel region CH of the active layer ACT. The gate insulating layer GTI may include at least one of tetraethylorthosilicate (TEOS), silicon nitride (SiNₓ), and silicon oxide (SiO₂). For example, the gate insulating layer GTI may have a double-layer structure in which a silicon nitride layer with a thickness of 40 nm and a tetraethylorthosilicate layer with a thickness of 80 nm are sequentially stacked.

The first gate electrode GE1 may be disposed on the gate insulating layer GTI. The first gate electrode GE1 may be disposed on the gate insulating layer GTI to overlap the channel region CH of the active layer ACT. The first gate electrode GE1 may be made of aluminum (Al) or titanium (Ti). In addition, the first gate electrode GE1 may have a double-layer or triple-layer structure in which aluminum (Al) and titanium (Ti) are stacked.

An interlayer insulating layer ITL may be disposed on the first gate electrode GE1. The interlayer insulating layer ITL may be disposed on the entire surface of the substrate SUB including the first gate electrode GE1. The interlayer insulating layer ITL may include an inorganic layer, for example, a silicon nitride layer, a silicon oxynitride layer, a silicon oxide layer, a titanium oxide layer, or an aluminum oxide layer. The interlayer insulating layer ITL may include a plurality of inorganic layers.

A source connection electrode SCE and a drain connection electrode DCE may be disposed on the interlayer insulating layer ITL. The source connection electrode SCE may be connected to a source electrode SE of the active layer ACT through a first contact hole CT1 penetrating the interlayer insulating layer ITL. The drain connection electrode DCE may be connected to a drain electrode DE of the active layer ACT through a second contact hole CT2 penetrating the interlayer insulating layer ITL. The source connection electrode SCE and the drain connection electrode DCE may be made of the same material as the first gate electrode GE1 described above.

A passivation layer PAS may be disposed on the source connection electrode SCE and the drain connection electrode DCE. The passivation layer PAS may be disposed on the entire surface of the substrate SUB including the interlayer insulating layer ITL. The passivation layer PAS may be made of the same material as the interlayer insulating layer ITL.

A planarization layer VA may be disposed on the passivation layer PAS. The planarization layer VA may be disposed on the entire surface of the substrate SUB including the passivation layer PAS. The planarization layer VA may include an organic layer such as acryl resin, epoxy resin, phenolic resin, polyamide resin, or polyimide resin.

The light emitting element layer EMTL including a pixel electrode PE, a light emitting element ED, and a pixel defining layer PDL may be disposed on the planarization layer VA. The pixel electrode PE may be connected to the source connection electrode SCE through a third contact hole CT3 penetrating the planarization layer VA. The pixel electrode PE may be connected to the source electrode SE of the active layer ACT through the source connection electrode SCE.

The light emitting element ED may include the pixel electrode PE, the light emitting layer EL, and a common electrode CM. An emission area EA is an area where the pixel electrode PE, the light emitting layer EL, and the common electrode CM are sequentially stacked so that holes from the pixel electrode PE and electrons from the common electrode CM are combined with each other in the light emitting layer EL to emit light. In this case, the pixel electrode PE may be an anode of the light emitting element ED, and the common electrode CM may be a cathode of the light emitting element ED.

In a top emission structure in which light is emitted in a direction from the light emitting layer EL toward the common electrode CM, the pixel electrode PE may be formed as a single layer of molybdenum (Mo), titanium (Ti), copper (Cu) or aluminum (Al) or, in order to increase reflectivity, may be formed as a stacked structure (Ti/Al/Ti) of aluminum and titanium, a stacked structure (ITO/Al/ITO) of aluminum and indium tin oxide, an APC alloy, or a stacked structure (ITO/APC/ITO) of an APC alloy and indium tin oxide. The APC alloy is an alloy of silver (Ag), palladium (Pd), and copper (Cu).

The pixel defining layer PDL defines emission areas EA of pixels. To this end, the pixel defining layer PDL may be disposed on the planarization layer VA to expose a portion of the pixel electrode PE. The pixel defining layer PDL may cover edges of the pixel electrode PE. The pixel defining layer PDL may be made of an organic layer such as acryl resin, epoxy resin, phenolic resin, polyamide resin, or polyimide resin.

A spacer SPC may be disposed on the pixel defining layer PDL. The spacer SPC may support a mask during a process of manufacturing the light emitting layer EL. The spacer SPC may be made of an organic layer such as acryl resin, epoxy resin, phenolic resin, polyamide resin, or polyimide resin.

The light emitting layer EL may be formed on the pixel electrode PE. The light emitting layer EL may include an organic material to emit light of a predetermined color. For example, the light emitting layer EL may include a hole transporting layer, an organic material layer, and an electron transporting layer. The organic material layer may include a host and a dopant. The organic material layer may include a material that emits predetermined light and may be formed using a phosphorescent material or a fluorescent material.

The pixels may include a first pixel that emits light of a first color through a first emission area, a second pixel that emits light of a second color through a second emission area, and a third pixel that emits light of a third color through a third emission area.

The organic material layer of a first light emitting layer of the first emission area emitting light of the first color may be a phosphorescent material that includes a host material including carbazole biphenyl (CBP) or 1,3-bis(carbazol-9-yl) (mCP) and a dopant including any one or more of bis(1-phenylisoquinoline) acetylacetonate iridium (PIQIr(acac)), bis(1-phenylquinoline) acetylacetonate iridium (PQIr(acac)), tris (1-phenylquinoline)iridium (PQIr) and octaethylporphyrin platinum (PtOEP). Alternatively, the organic material layer of the first light emitting layer of the first emission area may be a fluorescent material including PBD:Eu(DBM)3(Phen) or perylene. However, the present disclosure is not limited thereto.

The organic material layer of a second light emitting layer of the second emission area emitting light of the second color may be a phosphorescent material that includes a host material including CBP or mCP and a dopant material including Ir(ppy)3(fac tris(2-phenylpyridine)iridium). Alternatively, the organic material layer of the second light emitting layer of the second emission area emitting light of the second color may be a fluorescent material including tris (8-hydroxyquinolino) aluminum (Alq3). However, the present disclosure is not limited thereto.

The organic material layer of a third light emitting layer of the third emission area emitting light of the third color may be a phosphorescent material that includes a host material including CBP or mCP and a dopant material including (4,6-F2ppy)2Irpic or L2BD111. However, the present disclosure is not limited thereto.

The common electrode CM may be disposed on the light emitting layer EL. For example, the common electrode CM may be disposed on the first, second and third light emitting layers. The common electrode CM may cover the first, second and third light emitting layers. The common electrode CM may be a common layer commonly disposed on the first through third light emitting layers. A capping layer may be formed on the common electrode CM.

In the top emission structure, the common electrode CM may be made of a transparent conductive material (TCO) that can transmit light, such as indium tin oxide (ITO) or indium zinc oxide (IZO), or a semi-transmissive conductive material such as magnesium (Mg), silver (Ag) or an alloy of Mg and Ag. In case that the common electrode CM is made of a semi-transmissive conductive material, light output efficiency may be increased by a microcavity.

The encapsulation layer ENC may be formed on the light emitting element layer EMTL. The encapsulation layer ENC may include at least one inorganic layer TFE1 and TFE3 to prevent oxygen or moisture from penetrating into the light emitting element layer EMTL. In addition, the encapsulation layer ENC may include at least one organic layer to protect the light emitting element layer EMTL from foreign substances such as dust or other types of debris. For example, the encapsulation layer ENC may include a first encapsulating inorganic layer TFE1, an encapsulating organic layer TFE2, and a second encapsulating inorganic layer TFE3.

The first encapsulating inorganic layer TFEL may be disposed on the common electrode CM, the encapsulating organic layer TFE2 may be disposed on the first encapsulating inorganic layer TFE1, and the second encapsulating inorganic layer TFE3 may be disposed on the encapsulating organic layer TFE2. Each of the first encapsulating inorganic layer TFE1 and the second encapsulating inorganic layer TFE3 may be a multilayer in which one or more inorganic layers selected from a silicon nitride layer, a silicon oxynitride layer, a silicon oxide layer, a titanium oxide layer, and an aluminum oxide layer are alternately stacked. The encapsulating organic layer TFE2 may be an organic layer such as acryl resin, epoxy resin, phenolic resin, polyamide resin, or polyimide resin.

A barrier layer may be further disposed between the substrate SUB and the light blocking layer BML described above. The barrier layer may be a layer for protecting the transistors T1 through T3 of the thin-film transistor layer TFTL and the light emitting layer EL of the light emitting element layer EMTL from moisture introduced through the substrate SUB that is vulnerable to moisture penetration. The barrier layer may be composed of a plurality of inorganic layers stacked alternately. For example, the barrier layer may be a multilayer in which one or more inorganic layers selected from a silicon nitride layer, a silicon oxynitride layer, a silicon oxide layer, a titanium oxide layer, and an aluminum oxide layer are alternately stacked.

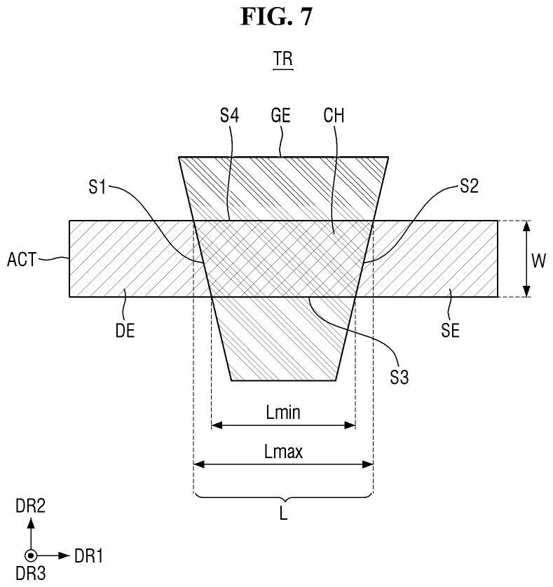

FIG. 7 is a plan view of a transistor TR according to an embodiment.

The transistor TR of the display device 10 according to the embodiment may include a gate electrode GE disposed on an active layer ACT to overlap the active layer ACT. Here, the gate electrode GE may be disposed on a gate insulating layer GTI to partially overlap the active layer ACT, thereby defining a channel region CH of the active layer ACT.

According to an embodiment, for example, in the channel region CH having a channel length L in the first direction DR1, at least one side of the channel region CH that defines the channel length L may have a diagonal or curved shape so that the channel length L varies along the second direction DR2 intersecting the first direction DR1. A specific example is described below as follows.

The transistor TR may include the gate electrode GE, a source electrode SE, and a drain electrode DE as illustrated in FIG. 7.

The active layer ACT may include the drain electrode DE, the source electrode SE, and the channel region CH of the transistor TR. The active layer ACT may have a rectangular shape.

The gate electrode GE may have a trapezoidal shape as illustrated in FIG. 7. The gate insulating layer GTI described above may be disposed between the gate electrode GE and the active layer ACT.

The gate electrode GE may overlap the active layer ACT. The channel region CH of the transistor TR may be formed in an area where the gate electrode GE and the active layer ACT overlap. For example, as illustrated in FIG. 7, the channel region CH may be defined as a region surrounded by a first side S1, a second side S2, a third side S3, and a fourth side S4.

A portion of the active layer ACT that is adjacent to a side of the channel region CH and not overlapped by the gate electrode GE may be defined as the drain electrode DE of the transistor TR, and a portion of the active layer ACT that is adjacent to the other side of the channel region CH and not overlapped by the gate electrode GE may be defined as the source electrode SE of the transistor TR.

The channel length L of the channel region CH may be defined as a distance between the drain electrode DE and the source electrode SE, and a channel width W of the channel region CH may be defined as lengths of facing surfaces of the drain electrode DE and the source electrode SE. For example, in FIG. 7, the channel length L may be defined as a distance in the channel region CH in the first direction DR1, and the channel width W may be defined as a distance in the channel region CH in the second direction DR2. The channel width W may be defined as, for example, a size of the first side S1 or the second side S2.

The channel region CH may have a trapezoidal shape as illustrated in FIG. 7. For example, the first side S1 and the second side S2 of the channel region CH that face each other may have a diagonal shape so that a distance between the first side S1 and the second side S2 (e.g., a distance in the first direction DR1) gradually increases along the second direction DR2. The third side S3 and the fourth side S4 that face each other may be shaped like straight lines parallel to each other. Here, the first side S1 and the second side S2 may have a diagonal shape so that they are symmetrical to each other with respect to the second direction DR2. A length of the fourth side S4 may be greater than a length of the third side S3.

As described above, since the first side S1 and the second side S2 have a diagonal shape, the length of the channel region CH may vary along the second direction DR2. For example, the channel length L of the channel region CH may gradually increase along the second direction DR2. In an embodiment, the channel region CH may have a minimum channel length Lmin at the third side S3 and may have a maximum channel length Lmax at the fourth side S4.

Since the channel length L of the channel region CH varies along the second direction DR2 as described above, the transistor TR may have a structure in which a plurality of sub-transistors having different channel lengths L are connected in parallel. Since the sub-transistors have different channel lengths L, threshold voltages (e.g., sub-threshold voltages) of the sub-transistors may have different values. Accordingly, a change in current (e.g., drain current) according to the threshold voltage of the transistor TR may be reduced. Therefore, a driving range of the transistor TR can be expanded, thus enabling detailed gradation expression, e.g., fine gradations.

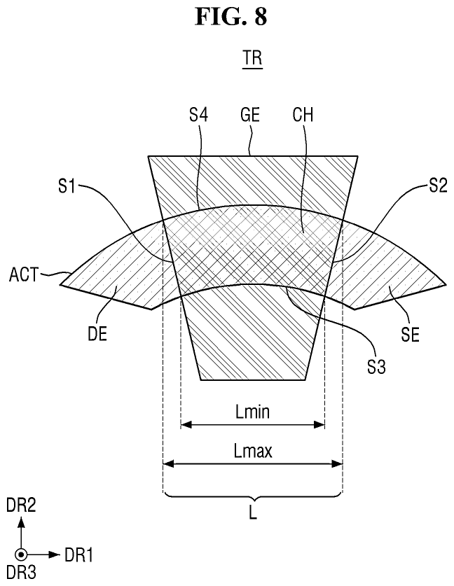

FIG. 8 is a plan view of a transistor TR according to an embodiment.

The transistor TR of FIG. 8 is different from the transistor TR of FIG. 7 in the shape of an active layer ACT and in the shape of a channel region CH. Therefore, the following description will focus on this difference for sake of brevity.

As illustrated in FIG. 8, the active layer ACT may have a curved shape (or a round shape). Accordingly, the channel region CH of the active layer ACT that overlaps a gate electrode GE may also have a curved shape. For example, among first through fourth sides S1 through S4 of the channel region CH, the third side S3 and the fourth side S4 that face each other in the second direction DR2 may have a curved shape (or a round shape). In an embodiment, each of the active layer ACT and the channel region CH may have an arc shape.

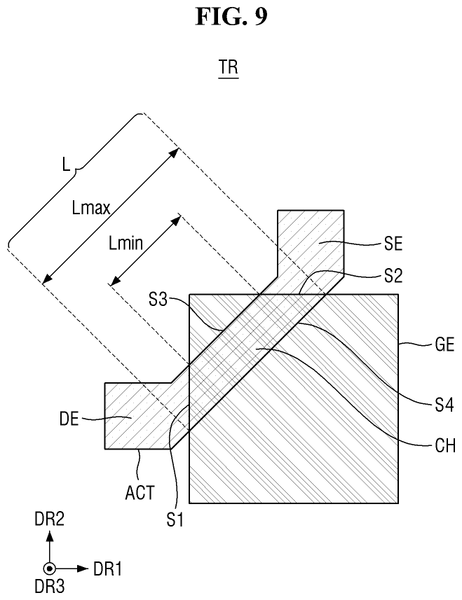

FIG. 9 is a plan view of a transistor TR according to an embodiment.

An active layer ACT may include a drain electrode DE, a source electrode SE, and a channel region CH of the transistor TR. The active layer ACT may have a rectangular shape with both sides bent.

A gate electrode GE may have a quadrangular shape as illustrated in FIG. 9. A gate insulating layer GTI may be disposed between the gate electrode GE and the active layer ACT.

The gate electrode GE may overlap the active layer ACT. The channel region CH of the transistor TR may be formed in an area where the gate electrode GE and the active layer ACT overlap. For example, as illustrated in FIG. 9, the channel region CH may be defined as a region surrounded by a first side S1, a second side S2, a third side S3, and a fourth side S4.

The channel region CH may have a trapezoidal shape as illustrated in FIG. 9. For example, the first side S1 and the second side S2 of the channel region CH that face each other may have a diagonal shape so that a distance between the first side S1 and the second side S2 gradually increases along a diagonal direction (hereinafter, referred to as a first diagonal direction) between the first direction DR1 and a reverse direction (hereinafter, referred to as a second reverse direction) of the second direction DR2. The third side S3 and the fourth side S4 that face each other may be shaped like straight lines parallel to each other. Here, the first side S1 and the second side S2 may have a diagonal shape so that they are symmetrical to each other with respect to the first diagonal direction.

As described above, since the first side S1 and the second side S2 have a diagonal shape, a length of the channel region CH may vary along the first diagonal direction. For example, a channel length L of the channel region CH may gradually increase along the first diagonal direction. In an embodiment, the channel region CH may have a minimum channel length Lmin at the third side S3 and may have a maximum channel length Lmax at the fourth side S4.

Since the channel length L of the channel region CH varies along the first diagonal direction as described above, the transistor TR may have a structure in which a plurality of sub-transistors having different channel lengths L are connected in parallel. Since the sub-transistors have different channel lengths L, threshold voltages (e.g., sub-threshold voltages) of the sub-transistors may have different values. Accordingly, a change in current (e.g., drain current) according to the threshold voltage of the transistor TR may be reduced. Therefore, a driving range of the transistor TR can be expanded, thus enabling detailed gradation expression, e.g., fine gradations.

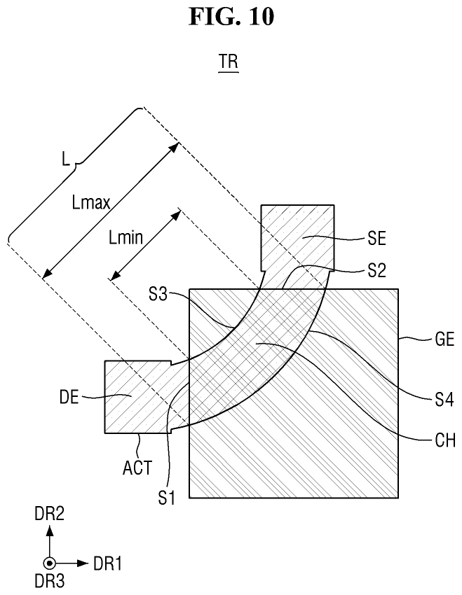

FIG. 10 is a plan view of a transistor TR according to an embodiment.

The transistor TR of FIG. 10 is different from the transistor TR of FIG. 9 in the shape of an active layer ACT and in the shape of a channel region CH. Therefore, the following description will focus on this difference for sake of brevity.

As illustrated in FIG. 10, the active layer ACT may have a curved shape (or a round shape). Accordingly, the channel region CH of the active layer ACT that overlaps a gate electrode GE may also have a curved shape. For example, among first through fourth sides S1 through S4 of the channel region CH, the third side S3 and the fourth side S4 that face each other in the first diagonal direction may have a curved shape (or a round shape). In an embodiment, each of the active layer ACT and the channel region CH may have an arc shape.

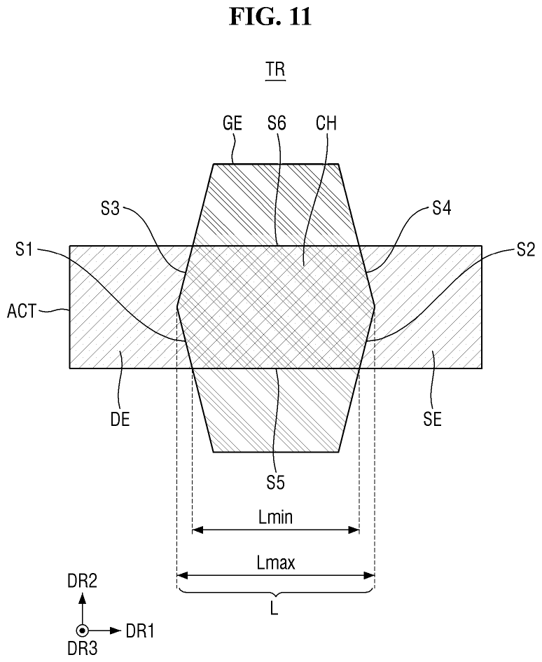

FIG. 11 is a plan view of a transistor TR according to an embodiment.

The transistor TR of FIG. 11 is different from the transistor TR of FIG. 7 in the shape of a gate electrode GE and in the shape of a channel region CH. Therefore, the following description will focus on this difference for sake of brevity.

As illustrated in FIG. 11, the gate electrode GE may have a polygonal (e.g., hexagonal) shape including six sides.

The channel region CH of an active layer ACT that overlaps the gate electrode GE of FIG. 11 may have a polygonal (e.g., hexagonal) shape including six sides S1 through S6. In other words, the channel region CH may be defined by first through sixth sides S1 through S6 in an overlap area between the active layer ACT and the gate electrode GE.

The first side S1 and the second side S2 of the channel region CH that face each other may have a diagonal shape so that a distance between the first side S1 and the second side S2 gradually increases along the second direction DR2. The third side S3 and the fourth side S4 of the channel region CH that face each other may have a diagonal shape so that a distance between the third side S3 and the fourth side S4 gradually decreases along the second direction DR2. In addition, the fifth side S5 and the sixth side S6 that face each other may be shaped like straight lines parallel to each other. Here, the first side S1 and the second side S2 may have a diagonal shape so that they are symmetrical to each other with respect to the second direction DR2. The third side S3 and the fourth side S4 may have a diagonal shape so that they are symmetrical to each other with respect to the second direction DR2. The first side S1 and the third side S3 neighboring each other may have a diagonal shape so that they are symmetrical to each other with respect to the first direction DR1. The second side S2 and the fourth side S4 neighboring each other may have a diagonal shape so that they are symmetrical to each other with respect to the first direction DR1.

As described above, since each of the first side S1, the second side S2, the third side S3, and the fourth side S4 has a diagonal shape, a channel length L of the channel region CH may vary along the second direction DR2. For example, the channel length L of the channel region CH may gradually increase along the second direction DR2 between the first side S1 and the second side S2 and may gradually decrease along the second direction DR2 between the third side S3 and the fourth side S4. In an embodiment, the channel region CH may have a minimum channel length Lmin at the fifth side S5 or the sixth side S6 and may have a maximum channel length Lmax between a vertex between the first side S1 and the third side S3 neighboring each other and a vertex between the second side S2 and the fourth side S4 neighboring each other.

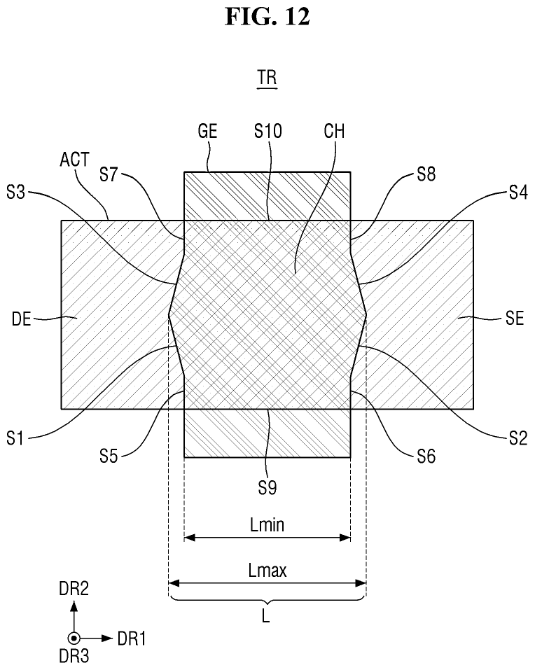

FIG. 12 is a plan view of a transistor TR according to an embodiment.

The transistor TR of FIG. 12 is different from the transistor TR of FIG. 7 in the shape of a gate electrode GE and in the shape of a channel region CH. Therefore, the following description will focus on this difference for sake of brevity.

As illustrated in FIG. 12, the gate electrode GE may have a polygonal shape including ten sides.

The channel region CH of an active layer ACT that overlaps the gate electrode GE of FIG. 12 may have a polygonal shape including ten sides S1 through S10. In other words, the channel region CH may be defined by first through tenth sides S1 through S10 in an overlap area between the active layer ACT and the gate electrode GE. For example, the channel region CH of FIG. 12 may have a polygonal shape including a first region having a quadrangular shape (e.g., a quadrangular region including S5, S6 and S9), a second region having a quadrangular shape (e.g., a quadrangular region including S7, S8 and S10), and a third region (e.g., a hexagonal region including S1, S2, S3 and S4) disposed between the first region and the second region and having a hexagonal shape.

The first side S1 and the second side S2 of the channel region CH that face each other may have a diagonal shape so that a distance between the first side S1 and the second side S2 gradually increases along the second direction DR2. The third side S3 and the fourth side S4 of the channel region CH that face each other may have a diagonal shape so that a distance between the third side S3 and the fourth side S4 gradually decreases along the second direction DR2. In addition, the fifth side S5 and the sixth side S6 that face each other may be shaped like straight lines parallel to each other, the seventh side S7 and the eighth side S8 that face each other may be shaped like straight lines parallel to each other, and the ninth side S9 and the tenth side S10 that face each other may be shaped like straight lines parallel to each other. Here, the first side S1 and the second side S2 may have a diagonal shape so that they are symmetrical to each other with respect to the second direction DR2. The third side S3 and the fourth side S4 may have a diagonal shape so that they are symmetrical to each other with respect to the second direction DR2. The first side S1 and the third side S3 neighboring each other may have a diagonal shape so that they are symmetrical to each other with respect to the first direction DR1. The second side S2 and the fourth side S4 neighboring each other may have a diagonal shape so that they are symmetrical to each other with respect to the first direction DR1.

As described above, since each of the first side S1, the second side S2, the third side S3, and the fourth side S4 has a diagonal shape, a channel length L of the channel region CH may vary along the second direction DR2. For example, the channel length L of the channel region CH may gradually increase along the second direction DR2 between the first side S1 and the second side S2 and may gradually decrease along the second direction DR2 between the third side S3 and the fourth side S4. In an embodiment, the channel region CH may have a minimum channel length Lmin at the ninth side S9 or the tenth side S10 and may have a maximum channel length Lmax between a vertex between the first side S1 and the third side S3 neighboring each other and a vertex between the second side S2 and the fourth side S4 neighboring each other.

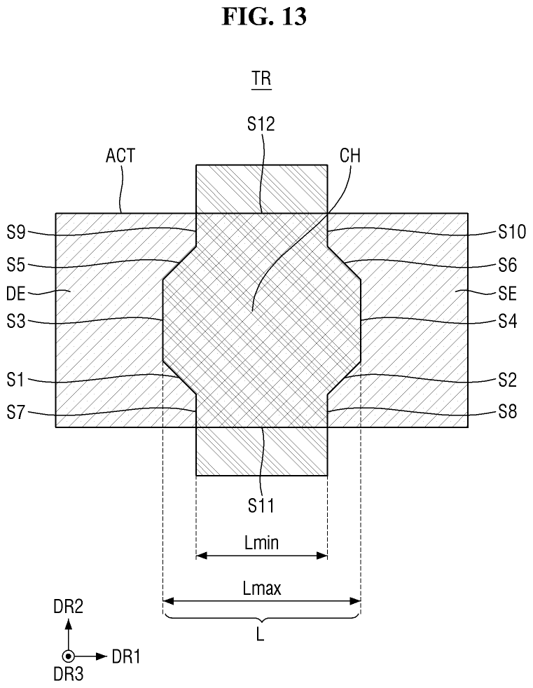

FIG. 13 is a plan view of a transistor TR according to an embodiment.

The transistor TR of FIG. 13 is different from the transistor TR of FIG. 7 in the shape of a gate electrode GE and in the shape of a channel region CH. Therefore, the following description will focus on this difference for sake of brevity.

As illustrated in FIG. 13, the gate electrode GE may have a polygonal shape including twelve sides.

The channel region CH of an active layer ACT that overlaps the gate electrode GE of FIG. 13 may have a polygonal shape including twelve sides S1 through S12. In other words, the channel region CH may be defined by first through twelfth sides S1 through S12 in an overlap area between the active layer ACT and the gate electrode GE. For example, the channel region CH of FIG. 13 may have a polygonal shape including a first region having a quadrangular shape (e.g., a quadrangular region including S7, S8 and S11), a second region having a quadrangular shape (e.g., a quadrangular region including S9, S10 and S12), and a third region (e.g., an octagonal region including S1, S2, S3, S4, S5 and S6) disposed between the first region and the second region and having an octagonal shape.

The first side S1 and the second side S2 of the channel region CH that face each other may have a diagonal shape so that a distance between the first side S1 and the second side S2 gradually increases along the second direction DR2. The fifth side S5 and the sixth side S6 of the channel region CH that face each other may have a diagonal shape so that a distance between the fifth side S5 and the sixth side S6 gradually decreases along the second direction DR2. In addition, the third side S3 and the fourth side S4 that face each other may be shaped like straight lines parallel to each other, the seventh side S7 and the eighth side S8 that face each other may be shaped like straight lines parallel to each other, the ninth side S9 and the tenth side S10 that face each other may be shaped like straight lines parallel to each other, and the eleventh side S11 and the twelfth side S12 that face each other may be shaped like straight lines parallel to each other. Here, the first side S1 and the second side S2 may have a diagonal shape so that they are symmetrical to each other with respect to the second direction DR2. The fifth side S5 and the sixth side S6 may have a diagonal shape so that they are symmetrical to each other with respect to the second direction DR2. The first side S1 and the fifth side S5 neighboring one side and the other side of the third side S3, respectively, may have a diagonal shape so that they are symmetrical to each other with respect to the first direction DR1. The second side S2 and the sixth side S6 neighboring one side and the other side of the fourth side S4, respectively, may have a diagonal shape so that they are symmetrical to each other with respect to the first direction DR1.

As described above, since each of the first side S1, the second side S2, the fifth side S5, and the sixth side S6 has a diagonal shape, a channel length L of the channel region CH may vary along the second direction DR2. For example, the channel length L of the channel region CH may gradually increase along the second direction DR2 between the first side S1 and the second side S2 and may gradually decrease along the second direction DR2 between the fifth side S5 and the sixth side S6. In an embodiment, the channel region CH may have a minimum channel length Lmin at the eleventh side S11 or the twelfth side S12 and may have a maximum channel length Lmax between the third side S3 and the fourth side S4 facing each other in the first direction DR1.

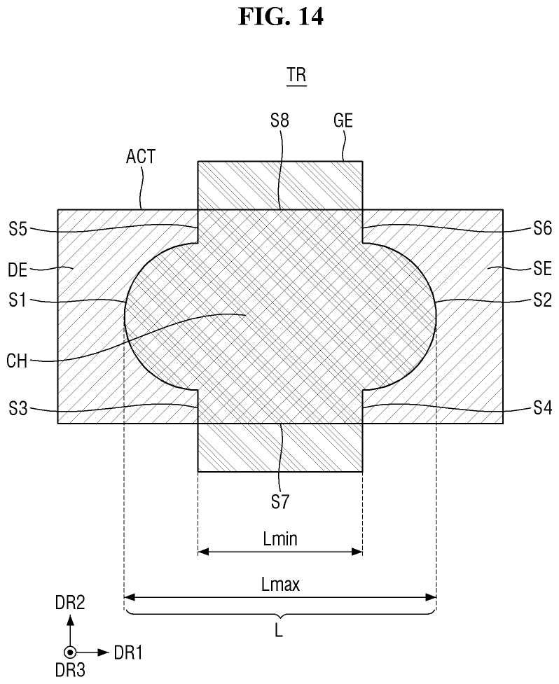

FIG. 14 is a plan view of a transistor TR according to an embodiment.

The transistor TR of FIG. 14 is different from the transistor TR of FIG. 7 in the shape of a gate electrode GE and in the shape of a channel region CH. Therefore, the following description will focus on this difference for sake of brevity.

As illustrated in FIG. 14, the gate electrode GE may have a polygonal shape including eight sides.

The channel region CH of an active layer ACT that overlaps the gate electrode GE of FIG. 14 may have a polygonal shape including eight sides S1 through S8. In other words, the channel region CH may be defined by first through eighth sides S1 through S8 in an overlap area between the active layer ACT and the gate electrode GE. Here, each of the first side S1 and the second side S2 that face each other in the first direction DR1 may have a parabolic (or curved) shape. For example, the first side S1 may have a parabolic shape that is convex in a reverse direction (hereinafter, referred to as a first reverse direction) of the first direction DR1, and the second side S2 may have a parabolic shape that is convex in the first direction DR1. The first side S1 and the second side S2 may be symmetrical to each other with respect to the second direction DR2. For example, the channel region CH of FIG. 14 may have a polygonal shape including a first region having a quadrangular shape (e.g., a quadrangular region including S3, S4 and S7), a second region having a quadrangular shape (e.g., a quadrangular region including S5, S6 and S8), and a third region (e.g., a region including S1 and S2) disposed between the first region and the second region and having an elliptical shape. The entire third region may be overlapped by the active layer ACT.

As described above, since each of the first side S1 and the second side S2 has a parabolic shape, a channel length L of the channel region CH may vary along the second direction DR2. For example, the channel length L of the channel region CH may gradually increase or gradually decrease along the second direction DR2 between the first side S1 and the second side S2. In an embodiment, the channel region CH may have a minimum channel length Lmin at the seventh side S7 or the eighth side S8 and may have a maximum channel length Lmax between a center of the first side S1 and a center of the second side S2.

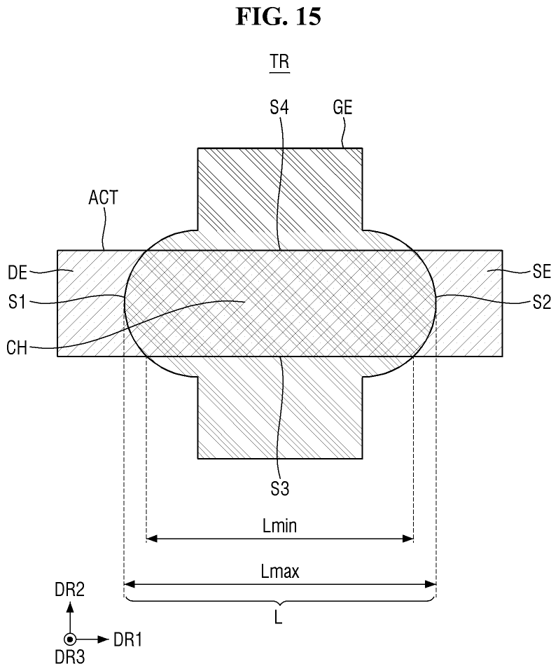

FIG. 15 is a plan view of a transistor TR according to an embodiment.

The transistor TR of FIG. 15 is different from the transistor TR of FIG. 14 in the shape of an active layer ACT and in the shape of a channel region CH. Therefore, the following description will focus on this difference for sake of brevity.

As illustrated in FIG. 15, the channel region CH may have a polygonal shape including four sides. In other words, the channel region CH may be defined by first through fourth sides S1 through S4 in an overlap area between the active layer ACT and a gate electrode GE. Here, each of the first side S1 and the second side S2 that face each other in the first direction DR1 may have a parabolic (or curved) shape. For example, the first side S1 may have a parabolic shape that is convex in a reverse direction (hereinafter, referred to as a first reverse direction) of the first direction DR1, and the second side S2 may have a parabolic shape that is convex in the first direction DR1. The first side S1 and the second side S2 may be symmetrical to each other with respect to the second direction DR2. For example, the channel region CH of FIG. 15 may have a polygonal shape including a first region having a quadrangular shape (e.g., a quadrangular region including S3, S4 and S7), a second region having a quadrangular shape (e.g., a quadrangular region including S5, S6 and S8), and a third region (e.g., a region including S1 and S2) disposed between the first region and the second region and having an elliptical shape. A portion of the third region may be overlapped by the active layer ACT.

As described above, since each of the first side S1 and the second side S2 has a parabolic shape, a channel length L of the channel region CH may vary along the second direction DR2. For example, the channel length L of the channel region CH may gradually increase or gradually decrease along the second direction DR2 between the first side S1 and the second side S2. In an embodiment, the channel region CH may have a minimum channel length Lmin at the third side S3 or the fourth side S4 and may have a maximum channel length Lmax between a center of the first side S1 and a center of the second side S2.

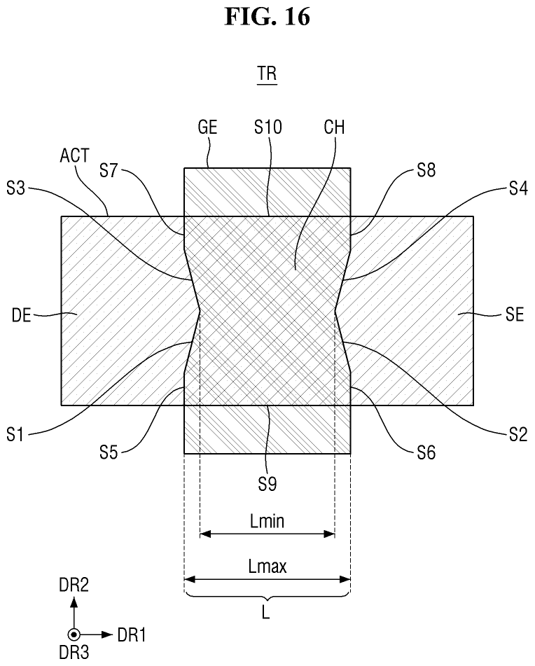

FIG. 16 is a plan view of a transistor TR according to an embodiment.

The transistor TR of FIG. 16 is different from the transistor TR of FIG. 12 in the shape of an active layer ACT and in the shape of a channel region CH. Therefore, the following description will focus on this difference for sake of brevity.

As illustrated in FIG. 16, a gate electrode GE may have a polygonal shape including ten sides.

As illustrated in FIG. 16, the channel region CH may have a polygonal shape including ten sides S1 through S10. In other words, the channel region CH may be defined by first through tenth sides S1 through S10 in an overlap area between the active layer ACT and the gate electrode GE.

The first side S1 and the second side S2 of the channel region CH that face each other may have a diagonal shape so that a distance between the first side S1 and the second side S2 gradually decreases along the second direction DR2. The third side S3 and the fourth side S4 of the channel region CH that face each other may have a diagonal shape so that a distance between the third side S3 and the fourth side S4 gradually increases along the second direction DR2. In addition, the fifth side S5 and the sixth side S6 that face each other may be shaped like straight lines parallel to each other, the seventh side S7 and the eighth side S8 that face each other may be shaped like straight lines parallel to each other, and the ninth side S9 and the tenth side S10 that face each other may be shaped like straight lines parallel to each other. Here, the first side S1 and the second side S2 may have a diagonal shape so that they are symmetrical to each other with respect to the second direction DR2. The third side S3 and the fourth side S4 may have a diagonal shape so that they are symmetrical to each other with respect to the second direction DR2. The first side S1 and the third side S3 neighboring each other may have a diagonal shape so that they are symmetrical to each other with respect to the first direction DR1. The second side S2 and the fourth side S4 neighboring each other may have a diagonal shape so that they are symmetrical to each other with respect to the first direction DR1. For example, the channel region CH of FIG. 16 may have a polygonal shape including a first region having a quadrangular shape (e.g., a quadrangular region including S5, S6 and S9), a second region having a quadrangular shape (e.g., a quadrangular region including S7, S8 and S10), a third region (e.g., a trapezoidal region including S1 and S2) disposed between the first region and the second region and having a trapezoidal shape, and a fourth region (e.g., an inverted trapezoidal region including S3 and S4) disposed between the second region and the third region and having an inverted trapezoidal shape.

As described above, since each of the first side S1, the second side S2, the third side S3, and the fourth side S4 has a diagonal shape, a channel length L of the channel region CH may vary along the second direction DR2. For example, the channel length L of the channel region CH may gradually decrease along the second direction DR2 between the first side S1 and the second side S2 and may gradually increase along the second direction DR2 between the third side S3 and the fourth side S4. In an embodiment, the channel region CH may have a maximum channel length Lmax at the ninth side S9 or the tenth side S10 and may have a minimum channel length Lmin between a vertex between the first side S1 and the third side S3 neighboring each other and a vertex between the second side S2 and the fourth side S4 neighboring each other.

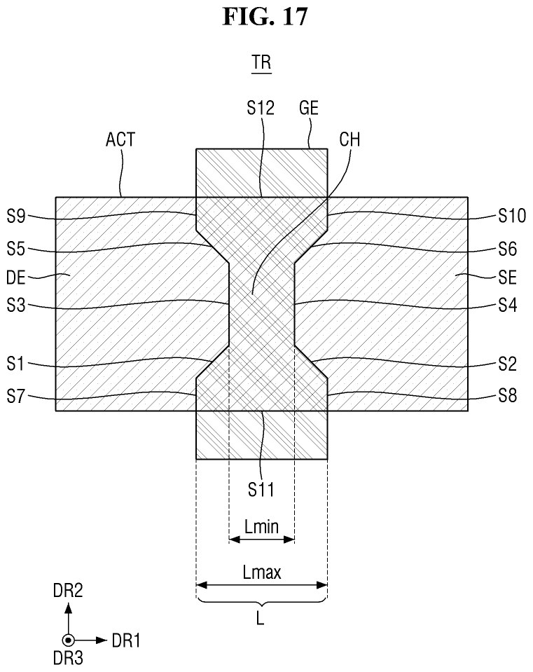

FIG. 17 is a plan view of a transistor TR according to an embodiment.

The transistor TR of FIG. 17 is different from the transistor TR of FIG. 13 in the shape of an active layer ACT and in the shape of a channel region CH. Therefore, the following description will focus on this difference for sake of brevity.

As illustrated in FIG. 17, a gate electrode GE may have a polygonal shape including twelve sides.

As illustrated in FIG. 17, the channel region CH may have a polygonal shape including twelve sides S1 through S12. In other words, the channel region CH may be defined by first through twelfth sides S1 through S12 in an overlap area between the active layer ACT and the gate electrode GE. For example, the channel region CH of FIG. 17 may have a polygonal shape including a first region having a quadrangular shape (e.g., a quadrangular region including S7, S8 and S11), a second region having a quadrangular shape (e.g., a quadrangular region including S9, S10 and S12), a third region (e.g., a trapezoidal region including S1 and S2) disposed between the first region and the second region and having a trapezoidal shape, a fourth region (e.g., an inverted trapezoidal region including S5 and S6) disposed between the third region and the second region and having an inverted trapezoidal shape, and a fifth region (e.g., a quadrangular region including S9, S10 and S12 disposed between the fourth region and the third region and having a quadrangular shape.

The first side S1 and the second side S2 of the channel region CH that face each other may have a diagonal shape so that a distance between the first side S1 and the second side S2 gradually decreases along the second direction DR2. The fifth side S5 and the sixth side S6 of the channel region CH that face each other may have a diagonal shape so that a distance between the fifth side S5 and the sixth side S6 gradually increases along the second direction DR2. In addition, the third side S3 and the fourth side S4 that face each other may be shaped like straight lines parallel to each other, the seventh side S7 and the eighth side S8 that face each other may be shaped like straight lines parallel to each other, the ninth side S9 and the tenth side S10 that face each other may be shaped like straight lines parallel to each other, and the eleventh side S11 and the twelfth side S12 that face each other may be shaped like straight lines parallel to each other. Here, the first side S1 and the second side S2 may have a diagonal shape so that they are symmetrical to each other with respect to the second direction DR2. The fifth side S5 and the sixth side S6 may have a diagonal shape so that they are symmetrical to each other with respect to the second direction DR2. The first side S1 and the fifth side S5 neighboring one side and the other side of the third side S3, respectively, may have a diagonal shape so that they are symmetrical to each other with respect to the first direction DR1. The second side S2 and the sixth side S6 neighboring one side and the other side of the fourth side S4, respectively, may have a diagonal shape so that they are symmetrical to each other with respect to the first direction DR1.

As described above, since each of the first side S1, the second side S2, the fifth side S5, and the sixth side S6 has a diagonal shape, a channel length L of the channel region CH may vary along the second direction DR2. For example, the channel length L of the channel region CH may gradually decrease along the second direction DR2 between the first side S1 and the second side S2 and may gradually increase along the second direction DR2 between the fifth side S5 and the sixth side S6. In an embodiment, the channel region CH may have a maximum channel length Lmax at the eleventh side S11 or the twelfth side S12 and may have a minimum channel length Lmin between the third side S3 and the fourth side S4 facing each other in the first direction DR1.

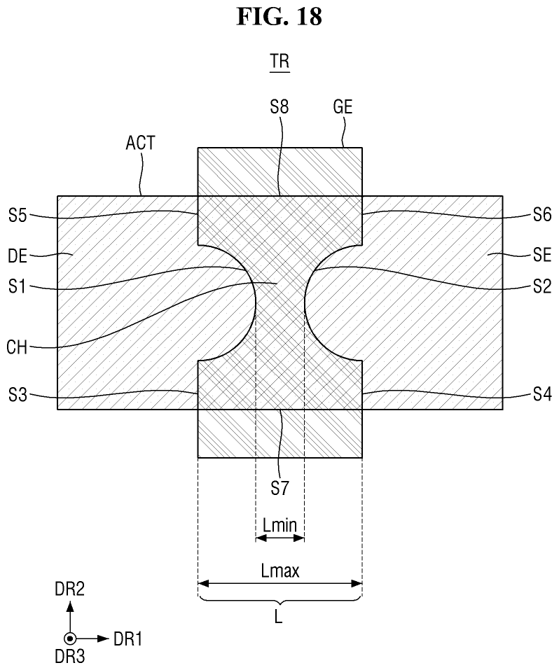

FIG. 18 is a plan view of a transistor TR according to an embodiment.

The transistor TR of FIG. 18 is different from the transistor TR of FIG. 14 in the shape of an active layer ACT and in the shape of a channel region CH. Therefore, the following description will focus on this difference for sake of brevity.

As illustrated in FIG. 18, a gate electrode GE may have a polygonal shape including eight sides.

As illustrated in FIG. 18, the channel region CH may have a polygonal shape including eight sides S1 through S8. In other words, the channel region CH may be defined by first through eighth sides S1 through S8 in an overlap area between the active layer ACT and the gate electrode GE. Here, each of the first side S1 and the second side S2 that face each other in the first direction DR1 may have a parabolic (or curved) shape. For example, the first side S1 may have a parabolic shape that is convex in the first direction DR1 (or concave in the first direction DR1), and the second side S2 may have a parabolic shape that is convex in the first reverse direction (or concave in the first reverse direction). The first side S1 and the second side S2 may be symmetrical to each other with respect to the second direction DR2. For example, the channel region CH of FIG. 18 may have semicircular grooves respectively formed on both sides facing each other in the first direction DR1.

As described above, since each of the first side S1 and the second side S2 has a parabolic shape, a channel length L of the channel region CH may vary along the second direction DR2. For example, the channel length L of the channel region CH may gradually increase or gradually decrease along the second direction DR2 between the first side S1 and the second side S2. In an embodiment, the channel region CH may have a maximum channel length Lmax at the seventh side S7 or the eighth side S8 and may have a minimum channel length Lmin between a center of the first side S1 and a center of the second side S2.

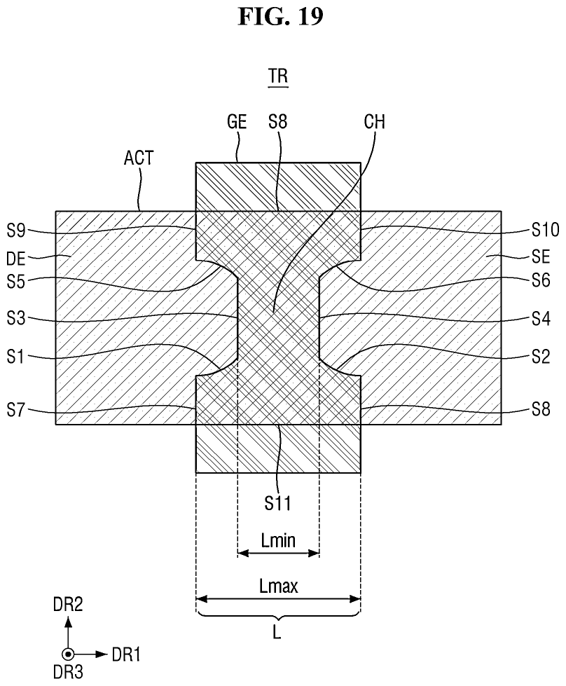

FIG. 19 is a plan view of a transistor TR according to an embodiment.

The transistor TR of FIG. 19 is different from the transistor TR of FIG. 17 in the shape of a gate electrode GE and in the shape of a channel region CH. Therefore, the following description will focus on this difference for sake of brevity.

As illustrated in FIG. 19, the gate electrode GE may have a polygonal shape including twelve sides.

As illustrated in FIG. 19, the channel region CH may have a polygonal shape including twelve sides S1 through S12. In other words, the channel region CH may be defined by first through twelfth sides S1 through S12 in an overlap area between an active layer ACT and the gate electrode GE.

The first side S1 and the second side S2 of the channel region CH that face each other may have a curved (or round) shape so that a distance between the first side S1 and the second side S2 gradually decreases along the second direction DR2. The fifth side S5 and the sixth side S6 of the channel region CH that face each other may have a curved (or round) shape so that a distance between the fifth side S5 and the sixth side S6 gradually increases along the second direction DR2. In addition, the third side S3 and the fourth side S4 that face each other may be shaped like straight lines parallel to each other, the seventh side S7 and the eighth side S8 that face each other may be shaped like straight lines parallel to each other, the ninth side S9 and the tenth side S10 that face each other may be shaped like straight lines parallel to each other, and the eleventh side S11 and the twelfth side S12 that face each other may be shaped like straight lines parallel to each other. Here, the first side S1 and the second side S2 may have a curved shape so that they are symmetrical to each other with respect to the second direction DR2. The fifth side S5 and the sixth side S6 may have a curved shape so that they are symmetrical to each other with respect to the second direction DR2. The first side S1 and the fifth side S5 neighboring one side and the other side of the third side S3, respectively, may have a curved shape so that they are symmetrical to each other with respect to the first direction DR1. The second side S2 and the sixth side S6 neighboring one side and the other side of the fourth side S4, respectively, may have a curved shape so that they are symmetrical to each other with respect to the first direction DR1. For example, the channel region CH of FIG. 19 may have semi-elliptical grooves respectively formed on both sides facing each other in the first direction DR1.

As described above, since each of the first side S1, the second side S2, the fifth side S5, and the sixth side S6 has a curved shape, a channel length L of the channel region CH may vary along the second direction DR2. For example, the channel length L of the channel region CH may gradually decrease along the second direction DR2 between the first side S1 and the second side S2 and may gradually increase along the second direction DR2 between the fifth side S5 and the sixth side S6. In an embodiment, the channel region CH may have a maximum channel length Lmax at the eleventh side S11 or the twelfth side S12 and may have a minimum channel length Lmin between the third side S3 and the fourth side S4 facing each other in the first direction DR1.

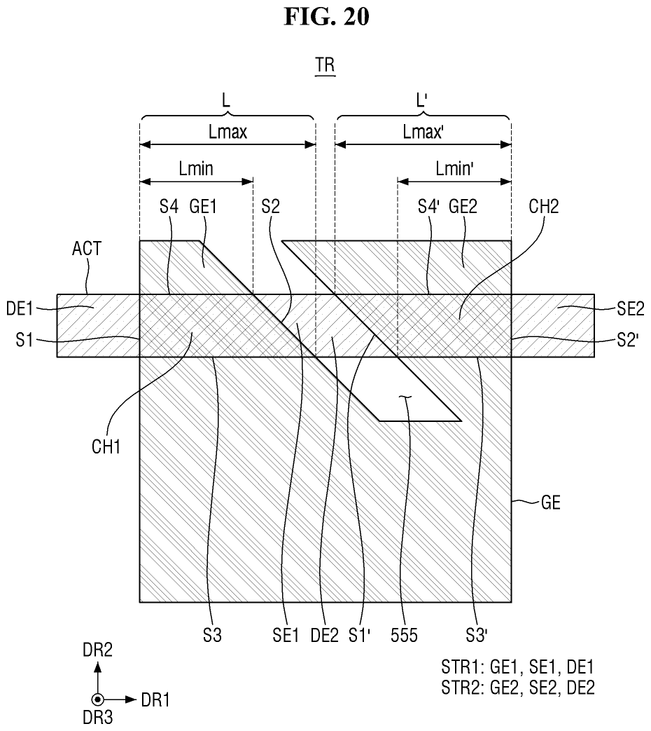

FIG. 20 is a plan view of a transistor TR according to an embodiment.

As illustrated in FIG. 20, a gate electrode GE may include a first gate electrode GE1 and a second gate electrode GE2.

The transistor TR of FIG. 20 may include a first sub-transistor STR1 and a second sub-transistor STR2 connected in series.

The first sub-transistor STR1 may include the first gate electrode GE1, a first drain electrode DE1, and a first source electrode SE1.

The second sub-transistor STR2 may include the second gate electrode GE2, a second drain electrode DE2, and a second source electrode SE2. The second drain electrode DE2 of the second sub-transistor STR2 may be connected to the first source electrode SE1 of the first sub-transistor STR1. For example, the second drain electrode DE2 and the first source electrode SE1 may be formed integrally with each other.

An active layer ACT may include the first drain electrode DE1, the first source electrode SE1, a first channel region CH1, the second drain electrode DE2, the second source electrode SE2, and a second channel region CH2. The active layer ACT may have a rectangular shape.

The first gate electrode GE1 may have a trapezoidal shape as illustrated in FIG. 20. A gate insulating layer GTI may be disposed between the first gate electrode GE1 and the active layer ACT.

The first gate electrode GE1 may overlap the active layer ACT. The first channel region CH1 of the first sub-transistor STR1 may be formed in an area where the first gate electrode GE1 and the active layer ACT overlap. For example, as illustrated in FIG. 20, the first channel region CH1 may be defined as a region surrounded by a first side S1, a second side S2, a third side S3, and a fourth side S4.

A portion of the active layer ACT that is adjacent to a side of the first channel region CH1 and not overlapped by the first gate electrode GE1 and the second gate electrode GE2 may be defined as the first drain electrode DE1 of the first sub-transistor STR1, and a portion of the active layer ACT that is adjacent to the other side of the first channel region CH1 and not overlapped by the first gate electrode GE1 and the second gate electrode GE2 may be defined as the first source electrode SE1 of the first sub-transistor STR1.

A channel length L of the first channel region CH1 may be defined as a distance between the first drain electrode DE1 and the first source electrode SE1, and a channel width of the first channel region CH1 may be defined as lengths of facing surfaces of the first drain electrode DE1 and the first source electrode SE1. For example, in FIG. 20, the channel length L may be defined as a distance in the first channel region CH1 in the first direction DR1, and the channel width may be defined as a distance in the first channel region CH1 in the second direction DR2. The channel width of the first channel region CH1 may be defined as, for example, a size of the first side S1 or the second side S2.

The first channel region CH1 may have a trapezoidal shape as illustrated in FIG. 20. For example, any one (e.g., the second side S2) of the first side S1 and the second side S2 of the first channel region CH1 that face each other may have a diagonal shape so that a distance between the first side S1 and the second side S2 (e.g., a distance in the first direction DR1) gradually decreases along the second direction DR2.

As described above, since the second side S2 has a diagonal shape, the channel length L of the first channel region CH1 may vary along the second direction DR2. For example, the channel length L of the first channel region CH1 may gradually decrease along the second direction DR2. In an embodiment, the first channel region CH1 may have a maximum channel length Lmax at the third side S3 and may have a minimum channel length Lmin at the fourth side S4.

The gate electrode GE may have a slit 555 located between the first gate electrode GE1 and the second gate electrode GE2, and the active layer ACT may be exposed by the slit 555. For example, the first source electrode SE1 and the second drain electrode DE2 of the active layer ACT may overlap the slit 555 of the gate electrode GE.

Since the channel length L of the first channel region CH1 varies along the second direction DR2, the first sub-transistor STR1 may have a structure in which a plurality of (1-1)^{th} sub-transistors having different channel lengths L are connected in parallel. Since the (1-1)^{th} sub-transistors have different channel lengths L, threshold voltages (e.g., sub-threshold voltages) of the (1-1)^{th} sub-transistors may have different values. Accordingly, a change in current (e.g., drain current) according to the threshold voltage of the first sub-transistor STR1 may be reduced. Therefore, a driving range of the first sub-transistor STR1 can be expanded, thus enabling detailed gradation expression, e.g., fine gradations.

The second gate electrode GE2 may have a trapezoidal shape as illustrated in FIG. 20. Here, the second gate electrode GE2 and the first gate electrode GE1 may be symmetrical to each other with respect to the first direction DR1. In other words, in case that the first gate electrode GE1 has a trapezoidal shape, the second gate electrode GE2 may have an inverted trapezoidal shape. A gate insulating layer GTI may be disposed between the second gate electrode GE2 and the active layer ACT.

The second gate electrode GE2 may overlap the active layer ACT. The second channel region CH2 of the second sub-transistor STR2 may be formed in an area where the second gate electrode GE2 and the active layer ACT overlap. For example, as illustrated in FIG. 20, the second channel region CH2 may be defined as a region surrounded by a first side S1′, a second side S2′, a third side S3′, and a fourth side S4′.

A portion of the active layer ACT that is adjacent to a side of the second channel region CH2 and not overlapped by the first gate electrode GE1 and the second gate electrode GE2 may be defined as the second drain electrode DE2 of the second sub-transistor STR2, and a portion of the active layer ACT that is adjacent to the other side of the second channel region CH2 and not overlapped by the first gate electrode GE1 and the second gate electrode GE2 may be defined as the second source electrode SE2 of the second sub-transistor STR2.

A channel length L′ of the second channel region CH2 may be defined as a distance between the second drain electrode DE2 and the second source electrode SE2, and a channel width of the second channel region CH2 may be defined as lengths of facing surfaces of the second drain electrode DE2 and the second source electrode SE2. For example, in FIG. 20, the channel length L′ may be defined as a distance in the second channel region CH2 in the first direction DR1, and the channel width may be defined as a distance in the second channel region CH2 in the second direction DR2. The channel width of the second channel region CH2 may be defined as, for example, a size of the first side S1′ or the second side S2′. The second channel region CH2 and the first channel region CH1 may be adjacent to each other in the first direction DR1.

The second channel region CH2 may have an inverted trapezoidal shape as illustrated in FIG. 20. For example, any one (e.g., the first side S1′) of the first side S1′ and the second side S2′ of the second channel region CH2 that face each other may have a diagonal shape so that a distance between the first side S1′ and the second side S2′ (e.g., a distance in the first direction DR1) gradually increases along the second direction DR2.

As described above, since the first side S1′ has a diagonal shape, the channel length L′ of the second channel region CH2 may vary along the second direction DR2. For example, the channel length L′ of the second channel region CH2 may gradually decrease along the second direction DR2. In an embodiment, the second channel region CH2 may have a minimum channel length Lmin′ at the third side S3′ and may have a maximum channel length Lmax′ at the fourth side S4′.

Since the channel length L′ of the second channel region CH2 varies along the second direction DR2, the second sub-transistor STR2 may have a structure in which a plurality of (1-2)^{th} sub-transistors having different channel lengths L′ are connected in parallel. Since the (1-2)^{th} sub-transistors have different channel lengths L′, threshold voltages (e.g., sub-threshold voltages) of the (1-2)^{th} sub-transistors may have different values. Accordingly, a change in current (e.g., drain current) according to the threshold voltage of the second sub-transistor STR2 may be reduced. Therefore, a driving range of the second sub-transistor STR2 can be expanded, thus enabling detailed gradation expression, e.g., fine gradations.

At least one of the transistors TR of FIGS. 7 through 20 described above may be applied to the first transistor T1 of FIG. 6. For example, the channel region CH of the first transistor T1 may have a variable channel length L, like the channel region CH of any one of the transistors TR of FIGS. 7 through 20.

In an embodiment, the first gate electrode GE1 and the active layer ACT of the first transistor T1 may have the same configuration as the gate electrode GE and the active layer ACT of any one of the transistors TR of FIGS. 7 through 20.

In addition, in an embodiment, the second gate electrode GE2 and the active layer ACT of the first transistor T1 may have the same configuration as the gate electrode GE and the active layer ACT of any one of the transistors TR of FIGS. 7 through 20.

In addition, in an embodiment, the first gate electrode GE1 and the second gate electrode GE2 of the first transistor T1 may have the same configuration as the gate electrode GE of any one of the transistors TR of FIGS. 7 through 20. In addition, the active layer ACT of the first transistor T1 may have the same configuration as the active layer ACT of any one of the transistors TR of FIGS. 7 through 20.

In addition, in an embodiment, the first gate electrode GE1 and the active layer ACT of the first transistor T1 may have the same configuration as the gate electrode GE and the active layer ACT of any one of the transistors TR of FIGS. 7 through 20. In addition, the second gate electrode GE2 of the first transistor T1 may have, for example, a quadrangular shape so that the channel region CH formed in an overlap area between the second gate electrode GE2 and the active layer ACT has a fixed channel length.

In addition, in an embodiment, the second gate electrode GE2 and the active layer ACT of the first transistor T1 may have the same configuration as the gate electrode GE and the active layer ACT of any one of the transistors TR of FIGS. 7 through 20. In addition, the first gate electrode GE1 of the first transistor T1 may have, for example, a quadrangular shape so that the channel region CH formed in an overlap area between the first gate electrode GE1 and the active layer ACT has a fixed channel length.

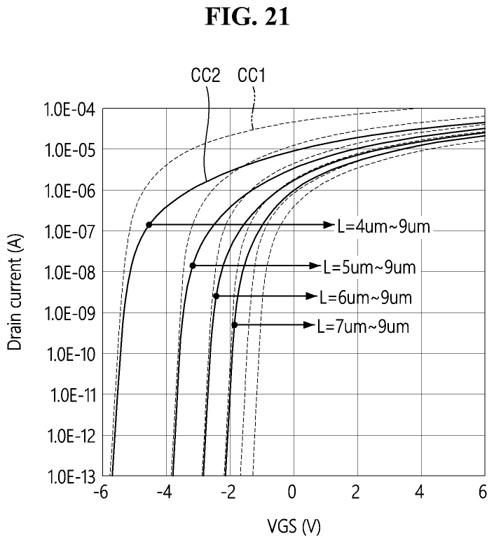

FIG. 21 is a diagram for explaining the effect of a transistor TR of a display device according to an embodiment.

FIG. 21 illustrates characteristic curves CC1 (hereinafter, referred to as first characteristic curves CC1) of a comparative transistor TR and characteristic curves CC2 (hereinafter, referred to as second characteristic curves CC2) of the transistor TR included in the display device according to the embodiment. The X-axis represents the magnitude of the gate-source voltage of the transistor TR, and the Y-axis represents the magnitude of the current (e.g., drain current) of the transistor TR.

The first characteristic curves CC1 are curves regarding the gate-source voltage and drain current for each channel length L in case that the channel length L of the transistor TR is fixed. For example, in FIG. 21, six first characteristic curves CC1 are sequentially illustrated from the left in the order of a (1-1)^{th} characteristic curve, a (1-2)^{th} characteristic curve, a (1-3)^{th} characteristic curve, a (1-4)^{th} characteristic curve, a (1-5)^{th} characteristic curve, and a (1-6)^{th} characteristic curve. Here, the (1-1)^{th} characteristic curve may be a characteristic curve in case that the channel length L of the transistor TR is about 4 μm. The (1-2)^{th} characteristic curve may be a characteristic curve in case that the channel length L of the transistor TR is about 5 μm. The (1-3)^{th} characteristic curve may be a characteristic curve in case that the channel length L of the transistor TR is about 6 μm. The (1-4)^{th} characteristic curve may be a characteristic curve in case that the channel length L of the transistor TR is about 7 μm. The (1-5)^{th} characteristic curve may be a characteristic curve in case that the channel length L of the transistor TR is about 8 μm. The (1-6)^{th} characteristic curve may be a characteristic curve in case that the channel length L of the transistor TR is about 9 μm.

The second characteristic curves CC2 are curves regarding the gate-source voltage and drain current for each range of channel lengths L in case that the channel length L of the transistor TR is variable. For example, in FIG. 21, four second characteristic curves CC2 are sequentially illustrated from the left in the order of a (2-1)^{th} characteristic curve, a (2-2)^{th} characteristic curve, a (2-3)^{th} characteristic curve, and a (2-4)^{th} characteristic curve. Here, the (2-1)^{th} characteristic curve may be a characteristic curve in case that the channel length L of the transistor TR is in a range of about 4 to about 9 μm. The (2-2)^{th} characteristic curve may be a characteristic curve in case that the channel length L of the transistor TR is in a range of about 5 to about 9 μm. The (2-3)^{th} characteristic curve may be a characteristic curve in case that the channel length L of the transistor TR is in a range of about 6 to about 9 μm. The (2-4)^{th} characteristic curve may be a characteristic curve in case that the channel length L of the transistor TR is in a range of about 7 to about 9 μm.

As illustrated in FIG. 21, the slopes of the second characteristic curves CC2 are smaller than the slopes of the first characteristic curves CC1. Therefore, the transistor TR included in the display device according to the embodiment can secure a wider driving range than the comparative transistor TR.

A display device according to the present disclosure can express fine gradations due to an expanded driving range.

In concluding the detailed description, those skilled in the art will appreciate that many variations and modifications may be made to the embodiments without substantially departing from the principles and spirit and scope of the present invention. Therefore, the disclosed embodiments are used in a generic and descriptive sense only and not for purposes of limitation.

What is claimed is:

1. A display device comprising:
an active layer disposed on a substrate;
a gate electrode disposed on the active layer to overlap the active layer and define a channel region of the active layer;
a pixel electrode disposed on the gate electrode;
a light emitting layer disposed on the pixel electrode; and
a common electrode disposed on the light emitting layer,
wherein in the channel region having a channel length in a first direction, at least one side of the channel region that defines the channel length has a diagonal shape or a curved shape such that the channel length varies in a second direction intersecting the first direction.

2. The display device of claim 1, wherein the channel region has a trapezoidal shape.

3. The display device of claim 2, wherein the gate electrode has a trapezoidal shape.

4. The display device of claim 3, wherein the active layer has a rectangular shape.

5. The display device of claim 2, wherein the gate electrode has a quadrangular shape.

6. The display device of claim 3, wherein the active layer has a quadrangular shape with both sides bent inwardly or outwardly with respect to each other.

7. The display device of claim 1, wherein the channel region has an arc shape.

8. The display device of claim 7, wherein the gate electrode has a trapezoidal shape.

9. The display device of claim 8, wherein the active layer has an arc shape.

10. The display device of claim 7, wherein the gate electrode has a quadrangular shape.

11. The display device of claim 10, wherein the active layer has an arc shape.

12. The display device of claim 1, wherein the channel region has a hexagonal shape.

13. The display device of claim 12, wherein the gate electrode has a hexagonal shape.

14. The display device of claim 1, wherein the channel region comprises:
a first region having a quadrangular shape;
a second region having a quadrangular shape; and
a third region disposed between the first region and the second region and having a hexagonal shape.

15. The display device of claim 1, wherein the channel region comprises:
a first region having a quadrangular shape;
a second region having a quadrangular shape; and
a third region disposed between the first region and the second region and having an octagonal shape.

16. The display device of claim 1, wherein the channel region comprises:
a first region having a quadrangular shape;
a second region having a quadrangular shape; and
a third region disposed between the first region and the second region and having an elliptical shape.

17. The display device of claim 16, wherein the entire third region overlaps the active layer.

18. The display device of claim 16, wherein a portion of the third region overlaps the active layer.

19. The display device of claim 1, wherein the channel region comprises:
a first region having a quadrangular shape;
a second region having a quadrangular shape;
a third region disposed between the first region and the second region and having a trapezoidal shape; and
a fourth region disposed between the second region and the third region and having an inverted trapezoidal shape.

20. The display device of claim 1, wherein the channel region comprises:
a first region having a quadrangular shape;
a second region having a quadrangular shape;
a third region disposed between the first region and the second region and having a trapezoidal shape;
a fourth region disposed between the third region and the second region and having an inverted trapezoidal shape; and
a fifth region disposed between the fourth region and the third region and having a quadrangular shape.

21. The display device of claim 1, wherein the channel region has semicircular grooves respectively formed on both sides facing each other in the first direction.

22. The display device of claim 1, wherein the channel region has semi-elliptical grooves respectively formed on both sides facing each other in the first direction.

23. The display device of claim 1, wherein the channel region comprises:
a first region having a trapezoidal shape; and
a second region spaced apart from the first region in the first direction and having an inverted trapezoidal shape.

24. An organic light emitting diode, comprising:
an active layer disposed on a substrate;
a gate electrode disposed on the active layer to overlap the active layer and define a channel region of the active layer;
wherein in the channel region having a channel length, at least one side of the channel region that defines the channel length has a diagonal shape or a curved shape such that the channel length varies in a direction different from a direction in which the channel length extends.
